(19) United States
(12) Patent Application Publication
(10) Pub. No.: US 2026/0239866 A1
(43) Pub. Date: Aug. 13, 2026

(54) DISPLAY DEVICE INCLUDING ALIGNMENT MARKS AND ELECTRONIC DEVICE INCLUDING THE SAME

(71) Applicant: SAMSUNG DISPLAY CO., LTD., YONGIN-SI (KR)

(72) Inventors: Su Yeon SIM, Yongin-si (KR); Jeong Woo PARK, Yongin-si (KR); Beom Shik KIM, Yongin-si (KR); Yu Kyung LEE, Yongin-si (KR)

(21) Appl. No.: 19/320,570

(22) Filed: Sep. 5, 2025

(30) Foreign Application Priority Data
Feb. 13, 2025 (KR) 10-2025-0018529

(51) Int. Cl. H10K 59/88; G02F 1/1333; G02F 1/1335; H10K 59/80

(52) U.S. Cl. CPC H10K 59/88; G02F 1/133354; G02F 1/133526; H10K 59/879

(57) ABSTRACT

Provided is a display device and an electronic device including the same. The display device includes a display panel including a display panel center, and a first panel alignment mark and a second panel alignment mark each spaced apart from the display panel center by a radial distance and spaced apart from each other by an arc length with respect to the display panel center, a lens assembly including a lens assembly center and a first optical alignment mark spaced apart from the lens assembly center by the radial distance.

This non-provisional patent application claims priority under 35 U.S.C. § 119 to Korean Patent Application No. 10-2025-0018529, filed on Feb. 13, 2025 in the Korean Intellectual Property Office, the entire disclosure of which is incorporated by reference herein in its entirety.

### TECHNICAL FIELD

The present disclosure relates to a display device and, more particularly to, a display device including alignment marks and an electronic device including the same.

### DISCUSSION OF THE RELATED ART

With the development of communications technology and media, display devices have become increasingly utilized to display images across diverse environments and applications. For example, various types of display devices, such as liquid crystal displays (LCDs) and organic light emitting displays (OLEDs), have achieved widespread adoption.

Stereoscopic image display device has been developed, where the display device divides an image and displays the divided image into a space in front of the display device by using a lens array. In some aspects, the stereoscopic image display device includes a binocular parallax type, where the binocular parallax type display device displays a left-eye image and a right-eye image separately to provide a three-dimensional (3D) effect due to binocular parallax. In some cases, the stereoscopic image display device includes a light field type, where the light field type display device converges light emitted from each lens of the lens array onto a view area to form multi-view stereoscopic images. In some cases, ongoing research focuses on a light field-type stereoscopic image display device that enhances the stereoscopic 3D image by increasing the number of view areas.

### SUMMARY

According to various embodiments of the present disclosure, a display device includes a display panel including a display panel center, and a first panel alignment mark and a second panel alignment mark each spaced apart from the display panel center by a radial distance and spaced apart from each other by an arc length with respect to the display panel center. The display device may further include a lens assembly including a lens assembly center and a first optical alignment mark spaced apart from the lens assembly center by the radial distance.

According to various embodiments of the present disclosure, a distance between the first panel alignment mark and the display panel center may be equal to a distance between the first optical alignment mark and the lens assembly center.

According to various embodiments of the present disclosure, the display panel center may be located at an intersection point of a first central axis crossing a second central axis of the display panel.

According to various embodiments of the present disclosure, the lens assembly center may be located at an intersection point of a third central axis crossing a fourth central axis of the lens assembly.

According to various embodiments of the present disclosure, the lens assembly further may include a first substrate, a second substrate, and a lens disposed between the first substrate and the second substrate.

According to various embodiments of the present disclosure, the lens assembly may may include a second optical alignment mark spaced apart from the lens assembly center by the radial distance.

According to various embodiments of the present disclosure a first straight line connecting the display panel center and the first panel alignment mark and a second straight line connecting the display panel center and the second panel alignment mark may form a first angle. A third straight line connecting the lens assembly center and the first optical alignment mark and a fourth straight line connecting the lens assembly center and the second optical alignment mark may form the first angle.

According to various embodiments of the present disclosure, the display panel center and the lens assembly center may overlap in a thickness direction of the display panel, wherein the thickness direction may be perpendicular to an upper surface of the display panel.

According to various embodiments of the present disclosure, the second panel alignment mark may overlap the first optical alignment mark in the thickness direction.

According to various embodiments of the present disclosure, the second straight line may coincide with a line obtained by rotating the first straight line clockwise by the first angle, and the fourth straight line may coincide with a line obtained by rotating the third straight line clockwise by the first angle.

According to various embodiments of the present disclosure, the lens assembly further include a second optical alignment mark spaced apart from the lens assembly center, a first straight line connecting the display panel center and the first panel alignment mark, a second straight line connecting the display panel center and the second panel alignment mark, a third straight line connecting the lens assembly center and the first optical alignment mark, and a fourth straight line connecting the lens assembly center and the second optical alignment mark. The first straight line and the second straight line may form a first angle. The third straight line and the fourth straight line may form the first angle. The first central axis and the third central axis may form the first angle.

According to various embodiments of the present disclosure, the second central axis and the fourth central axis may form the first angle.

According to various embodiments of the present disclosure, the first angle may be an acute angle.

According to various embodiments of the present disclosure, an electronic device includes a display panel including a display panel center, a first display panel portion, and a second display panel portion disposed adjacent to the first display panel portion, and a lens assembly including a lens assembly center, a first lens assembly portion, and a second lens assembly portion disposed adjacent to the first lens assembly portion. Each of the first display panel portion and the second display panel portion may include a first panel alignment mark and a second panel alignment mark each spaced apart from the display panel center by a radial distance and spaced apart from each other by an arc length with respect to the display panel center. Each of the first lens assembly portion and the second lens assembly portion may include a first optical alignment mark spaced apart from the lens assembly center by the radial distance.

According to various embodiments of the present disclosure, the second panel alignment mark of the first display panel portion may overlap the first optical alignment mark of the first lens assembly portion in a thickness direction of the display panel. The second panel alignment mark of the second display panel portion may overlap the first optical alignment mark of the second lens assembly portion in the thickness direction. The thickness direction may be perpendicular to an upper surface of the display panel.

According to various embodiments of the present disclosure, a portion of the first display panel portion and a portion of the second display panel portion meet may form a first central axis, and a portion of the first lens assembly portion and a portion of the second lens assembly portion meet may form a second central axis.

According to various embodiments of the present disclosure, a distance between the first panel alignment mark of the first display panel portion and the display panel center may be equal to a distance between the first panel alignment mark of the second display panel portion and the display panel center.

According to various embodiments of the present disclosure, an electronic device may include a processor providing an image signal, a display module receiving the image signal from the processor and displaying an image, and a power module supplying power to the display module. The display module may include a display panel including a display panel center, and a first panel alignment mark and a second panel alignment mark each spaced apart from the display panel center by a radial distance and spaced apart from each other by an arc length with respect to the display panel center, and a lens assembly including a lens assembly center and a first optical alignment mark spaced apart from the lens assembly center by the radial distance.

According to various embodiments of the present disclosure, a distance between the first panel alignment mark and the display panel center may be equal to a distance between the first optical alignment mark and the lens assembly center.

According to various embodiments of the present disclosure, the lens assembly further include a second optical alignment mark spaced apart from the lens assembly center by the radial distance.

According to embodiments of the present disclosure, the accuracy and precision of attachment of a lens assembly can be increased. Since a plurality of panel alignment marks are formed in each display panel portion, a moire phenomenon of a display device can be reduced, and the display quality of the display device can be improved.

### BRIEF DESCRIPTION OF THE DRAWINGS

Aspects of the present disclosure may be apparent and more readily appreciated from the following description of the embodiments in conjunction with the accompanying drawings in which:

FIG. 1 is an exploded perspective view of a display device according to an embodiment of the present disclosure;

FIG. 2 is a perspective view of the display device according to FIG. 1;

FIG. 3 is a cross-sectional view of a portion of a display device including emission areas;

FIG. 4 is a cross-sectional view of a first type of light field display configured to display a two-dimensional (2D) image;

FIG. 5 is a cross-sectional view of a first type of light field display configured to display a three-dimensional (3D) image;

FIG. 6 is a cross-sectional view of a second type of light field display configured to display a 2D image;

FIG. 7 is a cross-sectional view of a second type of light field display configured to display a 3D image;

FIG. 8 is a plan view of a display panel;

FIG. 9 illustrates an example of a moire phenomenon occurrence due to an optical lens disposed on the display panel;

FIG. 10 illustrates an example of tilting the optical lens disposed on the display panel to prevent the moire phenomenon;

FIG. 11 is a plan view of a display panel according to an embodiment of the present disclosure;

FIG. 12 is an enlarged view of portion H of FIG. 11;

FIG. 13 is a plan view of an optical lens according to an embodiment of the present disclosure;

FIG. 14 is an enlarged view of portion I of FIG. 13;

FIG. 15 is a plan view of a display device according to a first embodiment of the present disclosure;

FIG. 16 is an enlarged view of portion J1 of FIG. 15;

FIG. 17 is a plan view of a display device according to a second embodiment of the present disclosure;

FIG. 18 is an enlarged view of portion J2 of FIG. 17;

FIG. 19 is a block diagram of an electronic device according to an embodiment of the present disclosure; and

FIG. 20 is a schematic diagram of electronic devices according to various embodiments of the present disclosure.

### DETAILED DESCRIPTION

Embodiments of the present disclosure are explained in detail with reference to the accompanying drawings. However, the embodiments of the present disclosure are not necessarily limited to the embodiments disclosed herein, and may be embodied in many different forms. These embodiments are provided merely to make the disclosure complete and to fully inform one of ordinary skill in the art to which the invention according to the present disclosure belongs, and the invention according to the present disclosure is defined by the scope of the claims.

When a layer, region, or element is referred to as being formed on another layer, region, or element, the layer, region, or element can be directly or indirectly formed on the other layer, region, or element. For example, intervening layers, regions, or elements may be present between the layers, regions, or elements, respectively. Throughout this disclosure, like reference numerals refer to like components. The shapes, sizes, proportions, angles, numbers, etc. disclosed in the drawings to illustrate embodiments are examples and are not necessarily intended to be limiting to those shown herein. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Although terms such as “first,” “second,” and the like are used to describe various components, the components are not necessarily limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Embodiments of the present disclosure provide a display device including a display panel and a lens assembly, each comprising a set of alignment marks arranged radially around respective geometric centers. The alignment marks are spaced at equal radial distances from the centers and positioned at uniform angular intervals. This structural configuration enables precise rotational alignment between the display panel and the lens assembly.

By configuring the alignment marks in circular arrays, the display device minimizes moire interference that may arise from misalignment between the pixel array of the display panel and the optical lens array of the lens assembly. When the lens assembly is rotated by a predetermined moire-minimizing angle, the alignment marks of the lens assembly can accurately align with the alignment marks of the display panel in the thickness direction.

Embodiments of the present disclosure improve optical alignment precision during assembly process and enhance overall display quality in 2D and 3D modes. This alignment architecture enables consistent angular alignment across display devices of various sizes and pixel configurations, thereby reducing assembly error and improving optical performance.

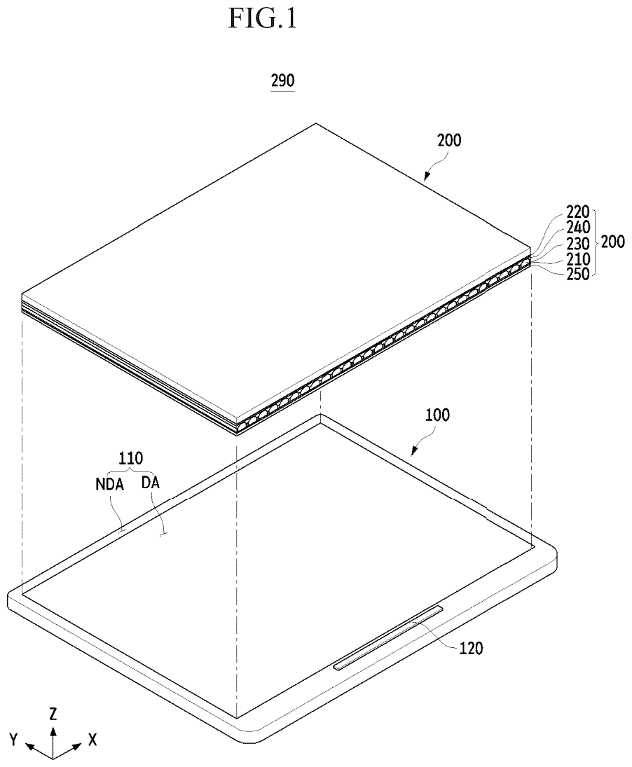

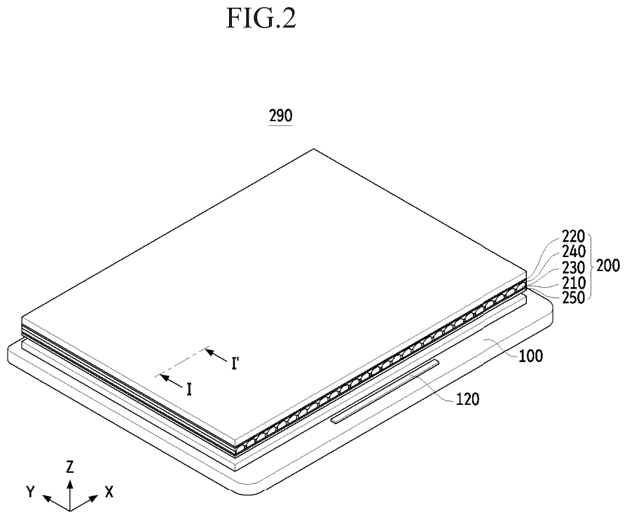

FIG. 1 is an exploded perspective view of a display device 290 according to an embodiment of the present disclosure. FIG. 2 is a perspective view of the display device 290 according to FIG. 1.

The display device 290 may be include a flat panel display device such as a liquid crystal display (LCD), a field emission display (FED), a plasma display panel (PDP), or an organic light emitting display (OLED).

In some cases, for example, the display device 290 may operate as a stereoscopic image display device, such as a three-dimensional (3D) image display device including a display module 100 and a lens assembly 200. To display a 3D image, the stereoscopic image display device may display a left-eye image and a right-eye image separately to provide a 3D effect based on binocular parallax. Furthermore, the stereoscopic image display device may provide a plurality of viewing angle images separately to show different images at different viewing angles. In some cases, the stereoscopic image display device may display these images on front of the device.

The display device 290 may include a light field display in which the lens assembly 200 is disposed in front of the display module 100 to deliver different image information to respective eyes of a viewer. The light field display may generate a light field and generate a 3D stereoscopic image by using the display module 100, where the display module 100 is configured to display a two-dimensional (2D) image. Then, the lens assembly 200 is configured to convert the 2D image into a 3D image and displays the 3D image (e.g., to the viewer or user). In the light field display, image display light generated by each pixel of the display module 100 is refracted to form a light field in a specific direction (e.g., a specific viewing angle and/or a specific point in time) by a stereoscopic lens, a pinhole, or a barrier included in the lens assembly 200. Accordingly, 3D stereoscopic image information mapped to the specific direction may be delivered to the corresponding viewing region to the viewer.

In one aspect, the display module 100 may include a display panel 110 and a display driver 120. The display panel 110 may include a display area DA and a non-display area NDA. The display area DA may include data lines, scan lines, voltage supply lines, and a plurality of pixels connected to corresponding data lines and scan lines. For example, the scan lines may extend in a first direction (e.g., an X-axis direction) and may be spaced apart from each other in a second direction (e.g., a Y-axis direction). The data lines and the voltage supply lines may extend in the second direction (e.g., the Y-axis direction) and may be spaced apart from each other in the first direction (e.g., the X-axis direction). In some cases, the first direction and the second direction may cross each other (or may be perpendicular to each other).

Each pixel (or unit pixel) formed and arranged in the display panel 110 may include a minimum number of subpixels capable of displaying a light having a white color. For example, each pixel may include three subpixels that display red light, green light, and blue light, respectively. Each of the subpixels, which are arranged alternately, may be connected to at least one scan line, a data line, and a power supply line. Each of the subpixels may include thin-film transistors, where the thin-film transistors include a driving transistor and at least one switching transistor, a light emitting element, and a capacitor. Each of the pixels may receive a data voltage of a data line when a scan signal is transmitted from a scan line and may emit light by supplying a driving current to a light emitting element based on the data voltage applied to a gate electrode.

In the present disclosure, the pixels (e.g., the unit pixels) of the display panel 110 are configured to display a 2D multi-view image based on the image data supply order of the display driver 120. The multi-view image includes n view images (where n is a natural number greater than or equal to 2). The n view images are images generated by capturing images of a specific object (or content) using n cameras spaced apart from each other by a distance approximating the distance between both eyes of an ordinary person (e.g., the viewer).

For example, the n view images may include first data generated by collecting specific content at a first viewing angle, second data generated by collecting the specific content at a second viewing angle, . . . , n^{th} data generated by collecting the specific content at an n^{th} viewing angle. A plurality of data (e.g., the first data through the n^{th} data) corresponding to image captures of the specific content from different angles may be provided as digital image data. For example, n is a positive integer greater than 1.

The display panel 110 may display a multi-view image in units of n pixels during an image display period. For example, the display panel 110 may display a multi-view image in units of two pixels, where each of the two pixels of the display panel 110 may display a multi-view image including two view images. In particular, the display panel 110 may display a multi-view image in units of a time-division frame (or subframe) period according to the time-division driving of the display driver 120. For example, a multi-view image may be displayed in units of two pixels for each time-division frame period. The time-division frame period is a period in which one frame period is divided into ½ or ⅓ frame periods.

The non-display area NDA may surround the display area DA at edges of the display panel 110. The non-display area NDA may include a scan driver configured to transmit scan signals to scan lines and pads which are connected to the display driver 120. For example, the display driver 120 may be disposed on a side of the non-display area NDA, and the pads may be disposed on an edge of the non-display area NDA adjacent to the display driver 120.

The display driver 120 may output control signals and image data voltages for driving the display panel 110 in units of at least one frame or in units of at least one time-division frame (or subframe). For example, the display driver 120 may supply image data voltages to data lines in units of at least one time-division frame (or subframe). The display driver 120 may supply a power supply voltage to a power supply line and may supply scan control signals to the scan driver. The image data voltages may include a plurality of data voltages which are supplied to a plurality of pixels (or subpixels) connected to a plurality of data lines.

The lens assembly 200 includes an optical lens 230 (e.g., refractive anisotropic lenses or a lens) which is formed and disposed between first and second base substrates 210 and 220, a polarization control unit 250 disposed on and overlapping the optical lens 230, and a filler layer 240 filling a space between the optical lens 230 and the second base substrate 220. In one aspect, the lens assembly 200 may be referred as the optical member. In one aspect, the lens assembly 200 includes the first base substrate 210, the optical lens 230 disposed on the first base substrate 210, the filler layer 240 disposed on the optical lens 230, the second base substrate 220 disposed on the filler layer 240, and the polarization control unit 250 disposed on the second base substrate 220.

The display driver 120 may be formed as an integrated circuit (IC) and mounted in the non-display area NDA of the display panel 110 using a chip on glass (COG) method, a chip on plastic (COP) method, or an ultrasonic bonding method. In an example, the display driver 120 may be mounted on a circuit board and electrically connected to the pads of the display panel 110.

The lens assembly 200 may be placed in front of the display panel 110 or the display module 100. The lens assembly 200 may be attached to a surface of the display panel 110 or the display area DA through an adhesive member. The lens assembly 200 may be bonded to the front of the display module 100 by a panel bonding device. For example, the lens assembly 200 and the display module 100 may be bonded using a clear adhesive.

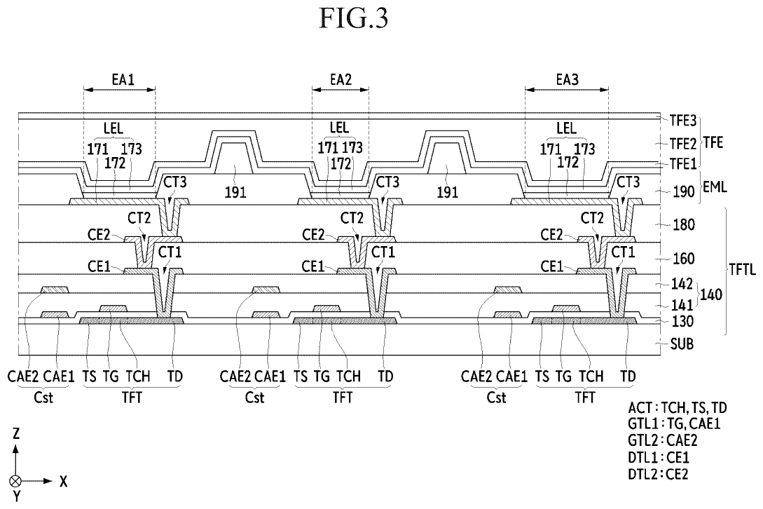

FIG. 3 is a cross-sectional view of a portion of a display device including emission areas.

Referring to FIG. 3, a display panel 110 may include a substrate SUB, a thin-film transistor layer TFTL, a light emitting element layer EML, and an encapsulation layer TFE.

The thin-film transistor layer TFTL may include an active layer ACT, a first gate metal layer GTL1, a second gate metal layer GTL2, a first data metal layer DTL1, and a second data metal layer DTL2. In one aspect, the thin-film transistor layer TFTL may include a buffer layer BF, a gate insulating layer 130, a first interlayer insulating film 141, a second interlayer insulating film 142, a first planarization layer 160, and a second planarization layer 180. The thin-film transistor layer TFTL may include a plurality of thin-film transistors TFT, and each of the thin-film transistors TFT may include a channel TCH, a gate electrode TG, a first electrode TS, and a second electrode TD.

The active layer ACT may be disposed on the substrate SUB. The active layer ACT may include a silicon semiconductor, such as polycrystalline silicon, monocrystalline silicon or low-temperature polycrystalline silicon, or an oxide semiconductor.

The active layer ACT may include the channel TCH, the first electrode TS and the second electrode TD of each of the thin-film transistors TFT. The channel TCH may be a region overlapped by the gate electrode TG of a thin-film transistor TFT in a third direction (e.g., a Z-axis direction) corresponding to a thickness direction of the substrate SUB. The first electrode TS may be located on a side of the channel TCH, and the second electrode TD may be located on the other side of the channel TCH. The first electrode TS and the second electrode TD may be regions not overlapped by the gate electrode TG in the third direction (e.g., the Z-axis direction). The first electrode TS and the second electrode TD may be regions formed to have conductivity by doping a silicon semiconductor or an oxide semiconductor with ions. In some cases, the first electrode TS and the second electrode TD may be formed by n-type or p-type ion doping using an ion implantation or diffusion process based on the transistor polarity.

The gate insulating layer 130 may be disposed on the active layer ACT. For example, the gate insulating layer 130 may include an inorganic layer, a silicon nitride layer, a silicon oxynitride layer, a silicon oxide layer, a titanium oxide layer, or an aluminum oxide layer. In some cases, the gate insulating layer 130 may cover an upper surface and side surfaces of the active layer ACT.

The first gate metal layer GTL1 may be disposed on the gate insulating layer 130. The first gate metal layer GTL1 may include the gate electrode TG of each of the thin-film transistors TFT and first capacitor electrodes CAE1. The first gate metal layer GTL1 may be a single layer or a multilayer including any one or more of metal elements including molybdenum (Mo), aluminum (Al), chromium (Cr), gold (Au), titanium (Ti), nickel (Ni), neodymium (Nd), copper (Cu), and alloys thereof.

The first interlayer insulating film 141 may be disposed on the first gate metal layer GTL1. The first interlayer insulating film 141 may include an inorganic layer, for example, a silicon nitride layer, a silicon oxynitride layer, a silicon oxide layer, a titanium oxide layer, or an aluminum oxide layer. In some cases, the first interlayer insulating film 141 may serve as a planarization layer.

The second gate metal layer GTL2 may be disposed on the first interlayer insulating film 141. The second gate metal layer GTL2 may include second capacitor electrodes CAE2. The second capacitor electrodes CAE2 may overlap the first capacitor electrodes CAE1 in the third direction (e.g., the Z-axis direction). Each capacitor Cst may include a first capacitor electrode CAE1 and a second capacitor electrode CAE2. The second gate metal layer GTL2 may be a single layer or a multilayer including one or more of metal materials such as molybdenum (Mo), aluminum (Al), chromium (Cr), gold (Au), titanium (Ti), nickel (Ni), neodymium (Nd), copper (Cu), and alloys thereof.

The second interlayer insulating film 142 may be disposed on the second gate metal layer GTL2. For example, the second interlayer insulating film 142 may include an inorganic layer, a silicon nitride layer, a silicon oxynitride layer, a silicon oxide layer, a titanium oxide layer, or an aluminum oxide layer. In some cases, the second interlayer insulating film 142 may serve as a planarization layer, where the upper surface of the second interlayer insulating film 142 may be substantially flat.

The first data metal layer DTL1 including first connection electrodes CE1 may be disposed on the second interlayer insulating film 142. Each of the first connection electrodes CE1 may be connected to the first electrode TS or the second electrode TD of a thin-film transistor TFT through a first contact hole CT1 penetrating the gate insulating layer 130, the first interlayer insulating film 141, and the second interlayer insulating film 142. The first data metal layer DTL1 may be a single layer or a multilayer including one or more of metal materials such as molybdenum (Mo), aluminum (Al), chromium (Cr), gold (Au), titanium (Ti), nickel (Ni), neodymium (Nd), copper (Cu), and alloys thereof.

The first planarization layer 160 may be disposed on the first data metal layer DTL1 to planarize steps caused by the active layer ACT, the first gate metal layer GTL1, the second gate metal layer GTL2, and the first data metal layer DTL1. The first planarization layer 160 may include an organic layer such as acryl resin, epoxy resin, phenolic resin, polyamide resin, or polyimide resin.

The second data metal layer DTL2 may be disposed on the first planarization layer 160. The second data metal layer DTL2 may include second connection electrodes CE2. Each of the second connection electrodes CE2 may be connected to a first connection electrode CE1 through a second contact hole CT2 penetrating the first planarization layer 160. The second data metal layer DTL2 may be a single layer or a multilayer including one or more metal materials such as molybdenum (Mo), aluminum (Al), chromium (Cr), gold (Au), titanium (Ti), nickel (Ni), neodymium (Nd), copper (Cu), and alloys thereof.

The second planarization layer 180 may be disposed on the second data metal layer DTL2. The second planarization layer 180 may include an organic layer such as acryl resin, epoxy resin, phenolic resin, polyamide resin, or polyimide resin.

The light emitting element layer EML may be disposed on the second planarization layer 180. The light emitting element layer EML may include a plurality of light emitting elements LEL and a pixel defining layer 190. Each of the light emitting elements LEL may be an organic light emitting diode element including a pixel electrode 171, a light emitting layer 172, and a common electrode 173.

The pixel electrode 171 may be disposed on the second planarization layer 180. The pixel electrode 171 may be connected to a second connection electrode CE2 through a third contact hole CT3 which penetrates the second planarization layer 180. In some cases, pixel electrode 171 may be in contact with the upper surface of the second electrode CE2 through the third contact hole CT3.

In a top emission structure in which light is emitted in a direction from the light emitting layer 172 toward the common electrode 173, the pixel electrode 171 may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer 190 may be disposed on the second planarization layer 180 to cover edges of each of the pixel electrodes 171. For example, the pixel defining layer 190 defines a plurality of emission areas EA1, EA2 and EA3. The pixel defining layer 190 may include an organic layer such as acryl resin, epoxy resin, phenolic resin, polyamide resin, or polyimide resin.

Each of the emission areas EA1, EA2 and EA3 is an area in which the pixel electrode 171, the light emitting layer 172, and the common electrode 173 are sequentially stacked so that holes from the pixel electrode 171 and electrons from the common electrode 173 recombine in the light emitting layer 172 to emit light. For each pixel, electrical current flows from the second electrode TD of the thin-film transistor TFT to the pixel electrode 171, through the light emitting layer 172, and into the common electrode 173, thereby enabling electroluminescence.

The light emitting layer 172 may be disposed on the pixel electrode 171. The light emitting layer 172 may include an organic material to emit light of a selected color. For example, the light emitting layer 172 may include a hole transporting layer, an organic material layer, and an electron transporting layer.

The common electrode 173 may be disposed on the light emitting layer 172. The common electrode 173 may cover the light emitting layer 172. The common electrode 173 may be a common layer formed in common in the emission areas EA1, EA2 and EA3. A capping layer may be formed on the common electrode 173.

In the top emission structure, the common electrode 173 may include a transparent conductive material (TCO) that can transmit light, such as indium tin oxide (ITO) or indium zinc oxide (IZO), or may include a semi-transmissive conductive material such as magnesium (Mg), silver (Ag) or an alloy of magnesium (Mg) and silver (Ag). When the common electrode 173 includes a semi-transmissive conductive material, light output efficiency may be increased by a microcavity.

Spacers 191 may be disposed on the pixel defining layer 190. The spacers 191 may support a mask during a process of forming the light emitting layers 172. The spacers 191 may include an organic layer such as acryl resin, epoxy resin, phenolic resin, polyamide resin, or polyimide resin. In some cases, the spacers 191 may be formed between the upper surface of the pixel defining layer 190 and a lower surface of the light emitting layers 172.

The encapsulation layer TFE may be located on the common electrode 173. The encapsulation layer TFE may include at least one inorganic layer to prevent oxygen or moisture from penetrating into the light emitting element layer EML. In some cases, the encapsulation layer TFE may include at least one organic layer to protect the light emitting element layer EML from foreign substances such as dust. For example, the encapsulation layer TFE may include a first encapsulating inorganic layer TFE1, an encapsulating organic layer TFE2, and a second encapsulating inorganic layer TFE3. In some cases, for example, the inorganic encapsulation layers TFE1 and TFE3 may be formed by atomic layer deposition, and the organic encapsulation layer TFE2 may be formed by spin-coating and thermal curing.

The first encapsulating inorganic layer TFE1 may be disposed on the common electrode 173, the encapsulating organic layer TFE2 may be disposed on the first encapsulating inorganic layer TFE1, and the second encapsulating inorganic layer TFE3 may be located on the encapsulating organic layer TFE2. Each of the first encapsulating inorganic layer TFE1 and the second encapsulating inorganic layer TFE3 may be a multilayer in which one or more inorganic layers of a silicon nitride layer, a silicon oxynitride layer, a silicon oxide layer, a titanium oxide layer, and an aluminum oxide layer alternately stacked. The encapsulating organic layer TFE2 may be an organic layer such as acryl resin, epoxy resin, phenolic resin, polyamide resin, or polyimide resin.

As illustrated in FIG. 3, a width measured in the first direction (e.g., the X-direction) of the third emission area EA3 may be larger than a width of a first emission area EA1, and a width of the first emission area EA1 may be larger than a width of a second emission area EA2. For example, the first emission area EA1 may be a red light-emitting area, the second emission area EA2 may be a green light-emitting area, and the third emission area EA3 may be a blue light-emitting area. However, embodiments of the present disclosure are not necessarily limited to the relative sizes of the emission areas.

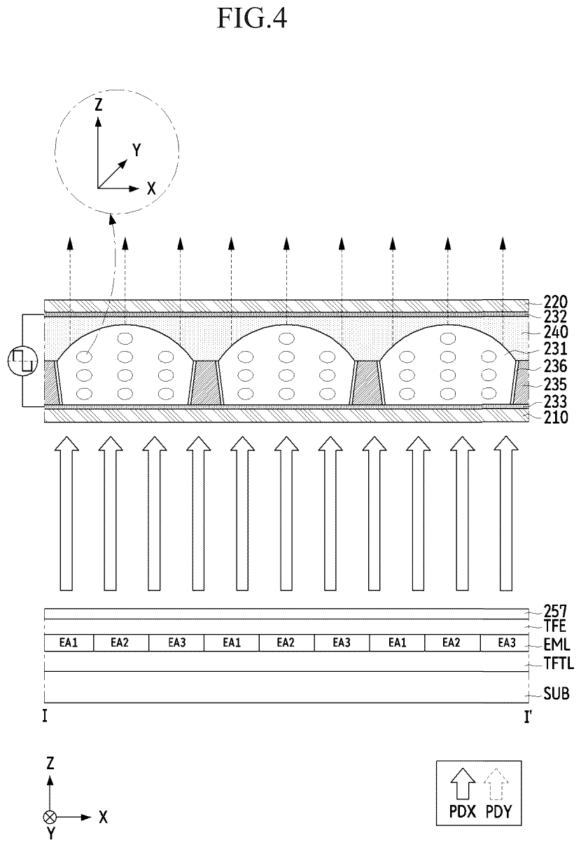

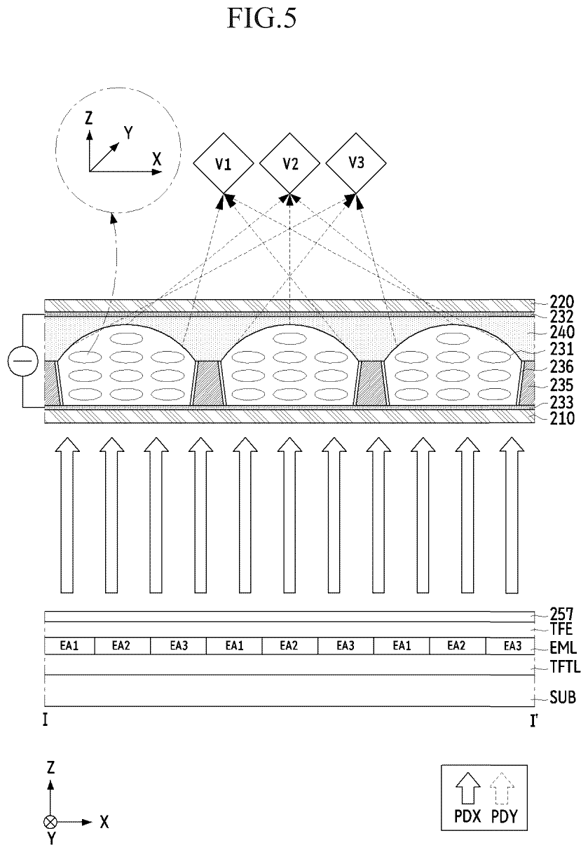

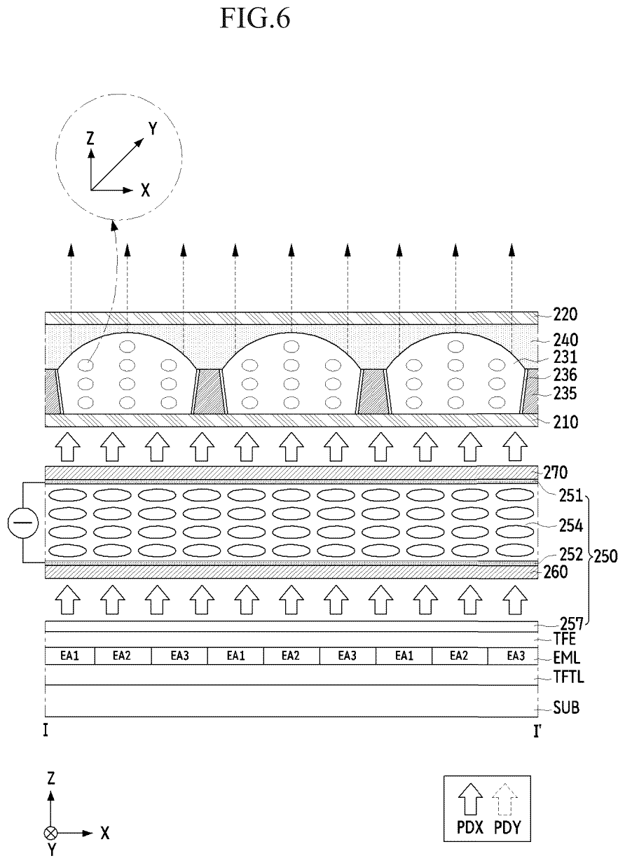

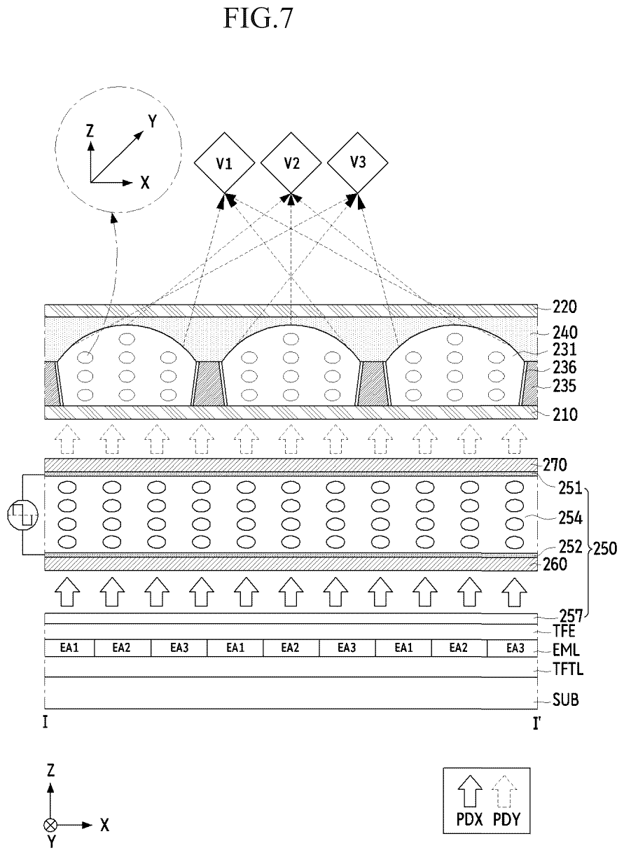

FIG. 4 is a cross-sectional view of a first type of light field display configured to display a 2D image. FIG. 5 is a cross-sectional view of a first type of light field display configured to display a 3D image. FIG. 6 is a cross-sectional view of a second type of light field display configured to display a 2D image. FIG. 7 is a cross-sectional view of a second type of light field display configured to display a 3D image.

In a light field display, a lens assembly is disposed in front of a display module as described above, so that different image information is shown to both eyes of a viewer. The light field display may realize a 2D image or a 3D image. For example, the term “in front” refers to a position along a Z-axis direction extending outward from a light-emitting surface of the display module, such that the lens assembly faces the viewer. In some cases, the lens assembly may be disposed on the display module. The light field display may realize display a 2D image or a 3D image.

In one aspect, specific content may include real world image data, such as text, pictures and objects, and digital data that are not from the real world. The specific content may be collected at a first viewing angle to produce first data. The specific content may be collected at a second viewing angle to produce second data. In some cases, when the specific content is collected at an n^{th} viewing angle, n^{th} data may be generated.

A display device may include a display panel in which a plurality of light emitting elements are disposed and a lens assembly disposed on the display panel. Light emitted from a light emitting element located in the display panel may or may not be refracted while passing through the lens assembly based on whether a 3D image is to be realized. For example, when a 3D image is to be realized, light emitted from a light emitting element may be refracted by the lens assembly. For example, when a 2D image is to be realized, light emitted from a light emitting element might not be refracted by the lens assembly.

However, even when a 2D image is to be realized, light emitted from a light emitting element may be refracted. For example, the resolution of the display device may be reduced.

A viewing angle may be assigned to each of the light emitting elements by adjusting a direction in which light emitted from the light emitting elements is refracted. This may be referred to as viewing angle mapping. The pitch, tilt angle, or orientation of a lens (e.g., a slanted lens) included in the lens assembly may be adjusted to control the direction of light emitted from the light emitting elements.

A specific viewing angle may be mapped to each of the light emitting elements, and light emitted from the mapped light emitting element may travel in the assigned viewing angle direction. For example, light emitted from a light emitting element to which the first viewing angle is mapped may travel in a first viewing angle direction in which a first view area is located, and light emitted from a light emitting element to which the second viewing angle is mapped may travel in a second viewing angle direction in which a second view area is located.

The first data generated by collecting specific content at the first viewing angle may be input to the light emitting element to which the first viewing angle is mapped. The second data may be input to the light emitting element to which the second viewing angle is mapped.

The first viewing angle may be located on a side (e.g., a left-eye side) of a midpoint between both eyes of a user. The second viewing angle may be located on the other side (e.g., a right-eye side) of the midpoint between both eyes of the user.

Regardless of which viewing angle is mapped, if different images are perceived by left and right eyes of a user, respectively, the user may feel that a 3D image is realized from the display device. If the same image is perceived by the left and right eyes of the user, the user may feel that a 2D image is realized from the display device. When light emitted from the display panel is not refracted, the same image may be perceived by the left and right eyes of the user. However, even if light emitted from the display panel is refracted, the same image may be perceived by the left and right eyes of the user. For example, the resolution of the display device may be reduced.

Therefore, a user may feel a 3D image from an image realized by inputting the first data to the light emitting element to which the first viewing angle is mapped and inputting the second data to the light emitting element to which the second viewing angle is mapped.

A user may perceive a 2D image generated by inputting the first data to both the light emitting element to which the first viewing angle is mapped and the light emitting element to which the second viewing angle is mapped. Light emitted from the light emitting element to which the first viewing angle is mapped is refracted even when a 2D image is generated, and light emitted from the light emitting element to which the second viewing angle is mapped is also refracted.

A 2D image may also be generated even when light emitted from a light emitting element is not refracted by the lens assembly. For example, a user may perceive a 2D image because the light emitted from the light emitting element is not refracted regardless of the viewing angle mapped to the light emitting element. The resolution of the 2D image realized thus may be relatively higher than the resolution of a 2D image realized when the same image is perceived by left and right eyes of a user even though light is refracted.

For example, a 2D image may be generated when light emitted from a light emitting element is not refracted by the lens assembly or when the same data is input to both eyes of a user even if the light is refracted. In some cases, the resolution may be different in each case.

Light field displays may include a switchable display configured to selectively realize a 2D image or a 3D image by controlling whether to refract light emitted from a display panel. The light field displays may include a non-switchable display which always refracts light emitted from a display panel. Even in the non-switchable display in which light emitted from the display panel is always refracted, a 2D image may be presented if the same data is input, regardless of the viewing angle mapped to a light emitting element. When a 2D image is presented in the non-switchable display, resolution may be reduced.

The switchable display may determine whether to display a 2D image or a 3D image by controlling a linear polarization direction of light emitted from the display panel and utilizing the refractive index anisotropy of a lens included in an optical lens.

For example, light emitted from the display panel may pass through a polarizing member located on the display panel and may exit along a path in a first linear polarization direction.

In an embodiment, a minor-axis direction of a lens included in the optical lens may coincide with the first linear polarization direction. A major-axis direction of the lens may coincide with a second linear polarization direction.

The optical lens may further include a filler layer disposed on a plurality of lenses. The lenses may have birefringence characteristics. For example, a refractive index of a lens in the minor-axis direction may be equal to a refractive index of the filler layer, and a refractive index of the lens in the major-axis direction may be greater than the refractive index of the filler layer. However, embodiments of the present disclosure are not necessarily limited to this example.

For example, if a voltage is applied to the lens, the minor-axis direction of the lens may be parallel to a path in the first linear polarization direction. When light having a path in the first linear polarization direction and emitted from the display panel passes through the lens, the light may experience the refractive index in the minor-axis direction which coincides with the first linear polarization direction. Since the refractive index of the lens in the minor-axis direction is equal to the refractive index of the filler layer, the light passing through the lens may travel straight without being refracted at an interface between the lens and the filler layer. For example, since the light is not refracted, the light perceived by both eyes of a user may be straight light, and the user may feel that a 2D image is displayed. This mechanism may be applied to a first type of light field display in which a 2D image is displayed (see FIG. 4).

In some cases, if no voltage is applied to the lens, the major-axis direction of the lens may be parallel to a path in the first linear polarization direction. When light having a path in the first linear polarization direction and emitted from the display panel passes through the lens, the light may experience the refractive index in the major-axis direction which coincides with the first linear polarization direction. Since the refractive index of the lens in the major-axis direction is greater than the refractive index of the filler layer, the light passing through the lens may be refracted at the interface between the lens and the filler layer. For example, since the light is refracted, the light perceived by both eyes of a user may be refracted light, and the user may feel that a 3D image is displayed. This mechanism may be applied to a first type of light field display in which a 3D image is displayed (see FIG. 5).

In a second type of light field display, no voltage may be applied to the lens, and the minor-axis direction and the major-axis direction of the lens may be fixed to be parallel to the first linear polarization direction and the second linear polarization direction, respectively (see FIGS. 6 and 7). Instead, light having a path in the first linear polarization direction and emitted from the display panel may pass through driving liquid crystals located between driving electrodes. The light passing through the driving liquid crystals to which no voltage is applied may maintain the path in the first linear polarization direction (see FIG. 6). The light passing through the driving liquid crystals to which a voltage is applied may switching from the first linear polarization direction to a path in the second linear polarization direction (see FIG. 7), thereby enabling mode control without reconfiguring the lens system.

Since the minor-axis direction and the major-axis direction of the lens are parallel to the first linear polarization direction and the second linear polarization direction, respectively, light passing through the driving liquid crystals with the first linear polarization direction, the light may experience the refractive index of the lens in the minor-axis direction. Light with the second linear polarization direction, the light may experience the refractive index of the lens in the major-axis direction. The refractive index of the lens in the minor-axis direction is equal to the refractive index of the filler layer, and the refractive index of the lens in the major-axis direction is greater than the refractive index of the filler layer. Therefore, whether the light exiting the driving liquid crystals will be refracted at the interface between the lens and the filling layer may be determined by the linear polarization direction of the light passing through the driving liquid crystals.

As described above, switchable light field displays may include a first type of light field display (see FIGS. 4 and 5) and a second type of light field display (see FIGS. 6 and 7).

In the first type of light field display, the linear polarization direction of light passing through a display panel is not changed as described above. Instead, the first type of light field display may directly change the major-axis direction and the minor-axis direction of a lens having birefringence characteristics. A changed axial direction may coincide with the linear polarization direction of the light passing through the display panel, and the light may pass through an interface while experiencing a refractive index in the changed axial direction.

In the second type of light field display, the linear polarization direction of light passing through a display panel may be changed as the light passes through driving liquid crystals. In contrast, the second type of light field display might not directly change the major-and minor-axis directions of a lens having birefringence characteristics. Therefore, the linear polarization direction of the light passing through the driving liquid crystals may coincide with a fixed axial direction of the lens, and the light may pass through an interface while experiencing a refractive index in the fixed axial direction.

Referring to FIGS. 6 and 7, in the second type of light field display, the display panel may include a substrate SUB, a thin-film transistor layer TFTL, a light emitting element layer EML, and an encapsulation layer TFE.

The substrate SUB may have rigidity to support elements formed on the substrate SUB. For example, the substrate SUB may be a glass substrate or a plastic substrate such as polyethylene terephthalate (PET).

The thin-film transistor layer TFTL may be disposed on the substrate SUB. The thin-film transistor layer TFTL may control the brightness of the display device 290. The thin-film transistor layer TFTL may include transistors.

The light emitting element layer EML may be disposed on the thin-film transistor layer TFTL. The light emitting element layer EML may include first through third emission areas EA1, EA2, and EA3. The first through third emission areas EA1 through EA3 may be alternately arranged along an X-direction, where the emission areas EA1, EA2, and EA3 are disposed on the light emitting element layer EML.

The encapsulation layer TFE may be located on the light emitting element layer EML. The encapsulation layer TFE may include at least one inorganic layer and at least one organic layer to encapsulate the light emitting element layer EML.

A lens assembly may include an optical lens disposed between a first base substrate 210 and a second base substrate 220. The optical lens may include a plurality of lenses 231 and a black matrix 235, light reflectors 236, or other optical elements positioned between the lenses 231. The lens assembly may include a filler layer 240 disposed between the first base substrate 210 and the second base substrate 220. Although the filler layer 240 is illustrated as being positioned on the optical lens, embodiments of the present disclosure are not necessarily limited hereto. For example, light passing through the display panel may also pass through the filler layer 240 first and then pass through the optical lens. In some cases, although the lenses 231 in the optical lens are convex in the third direction (e.g., the Z-axis direction), embodiments of the present disclosure are not necessarily limited hereto.

As described above, a refractive index range of a material having refractive index anisotropy in the lenses 231 and a refractive index value of the filler layer 240 are adjusted, and whether light is to be refracted is determined based on the presence or absence of a difference in refractive index. Therefore, the vertical relationship between the optical lens and the filler layer 240, the convex direction of the lenses 231, and other structural parameters are within a range that can be designed and modified.

The first base substrate 210, the second base substrate 220, a third base substrate 260, and a fourth base substrate 270 may include a material through which light can pass, such as glass or plastic.

A polarization control unit 250 may be formed behind the first base substrate 210 or in front of the display panel in order to switch 2D image display light of the display panel to a path PDX or PDY in the first linear polarization direction or the second linear polarization direction and output the 2D image display light along the path PDX or PDY in the first linear polarization direction or the second linear polarization direction. The polarization control unit 250 may include a first driving electrode 251, a second driving electrode 252, and driving liquid crystals 254 disposed between the first driving electrode 251 and the second driving electrode 252. The polarization control unit 250 may further include a polarizing member 257 disposed on the display panel.

The polarization control unit 250 may control light, which is incident along a path PDX in the first linear polarization direction through the polarizing member 257, to pass through the polarization control unit 250 along the path PDX in the first linear polarization direction or may switch the light to a path PDY in the second linear polarization direction and control the light to pass through the polarization control unit 250 along the path PDY in the second linear polarization direction.

The polarization control unit 250 may also switch light, which is incident along a path PDX in the first linear polarization direction through the polarizing member 257, to a path in an arbitrary linear polarization direction between the first linear polarization direction and the second linear polarization direction and may control the light to pass through the polarization control unit 250 along the path in the arbitrary linear polarization direction.

For example, the first linear polarization direction may be parallel to the first direction (e.g., the X-axis direction), and the second linear polarization direction may be parallel to the second direction (e.g., the Y-axis direction), but embodiments of the present disclosure are not necessarily limited hereto.

At least some elements (e.g., first driving electrode 251, second driving electrode 252, and driving liquid crystals 254) of the polarization control unit 250 may be disposed between the third base substrate 260 and the fourth base substrate 270. The other element (e.g., polarizing member 257) of the polarization control unit 250 may be disposed between the display panel and the third base substrate 260.

The first driving electrode 251 may be disposed between the third base substrate 260 and the fourth base substrate 270. A voltage may be applied to the first driving electrode 251.

The second driving electrode 252 may be disposed between the third base substrate 260 and the first driving electrode 251. The second driving electrode 252 may be parallel to the first driving electrode 251. The shape of the second driving electrode 252 may correspond to the shape of the first driving electrode 251. A voltage may be applied to the second driving electrode 252. The driving liquid crystals 254 may control the linear polarization direction of light based on a difference between the voltage applied to the first driving electrode 251 and the voltage applied to the second driving electrode 252.

The polarizing member 257 may be disposed between the display panel and the third base substrate 260. Light emitted from the display panel may vibrate in all directions. The polarizing member 257 may transmit only light vibrating in a specific direction among the light emitted from the display panel and may block the rest. In an embodiment, the polarizing member 257 may transmit only light having a path PDX in the first linear polarization direction among the light emitted from the display panel, but embodiments of the present disclosure are not necessarily limited hereto.

The driving liquid crystals 254 may be disposed between the first driving electrode 251 and the second driving electrode 252. The driving liquid crystals 254 may include liquid crystals that are birefringent materials. The arrangement of the driving liquid crystals 254 may vary according to the difference between the voltages applied to the first driving electrode 251 and the second driving electrode 252. The driving liquid crystals 254 may be twisted nematic (TN) liquid crystals.

Referring to FIG. 6, the difference between the voltage applied to the first driving electrode 251 and the voltage applied to the second driving electrode 252 during a 2D image display period may be less than a predetermined value. The driving liquid crystals 254 may maintain the linear polarization direction of incident light having a path PDX in the first linear polarization direction. The light passing through the driving liquid crystals 254 may retain the path PDX in the first linear polarization direction.

Referring to FIG. 7, the difference between the voltage applied to the first driving electrode 251 and the voltage applied to the second driving electrode 252 during a 3D image display period may be equal to or greater than the predetermined value. The driving liquid crystals 254 may change the linear polarization direction of incident light having a path PDX in the first linear polarization direction. The light passing through the driving liquid crystals 254 may follow a path PDY in the second linear polarization direction.

Referring again to FIGS. 6 and 7, the first base substrate 210, the second base substrate 220, and the optical lens disposed between the first base substrate 210 and the second base substrate 220 may be disposed on the fourth base substrate 270. The optical lens may be formed in the form of a lens sheet including lenses arranged side by side. The polarization control unit 250 may be stacked and overlapped with the optical lens formed as a lens sheet.

The optical lens may include the lenses 231, the black matrix 235, and the light reflectors 236.

Light passing through the lenses 231 may experience a refractive index of the lenses 231 in the major-axis direction, a refractive index in the minor-axis direction, or an intermediate refractive index corresponding to a direction between the major axis and the minor axis, based on the arrangement of birefringent materials (e.g., liquid crystals or slits) included in the lenses 231. These intermediate refractive indices between the major axis and the minor axis of each of the lenses 231 may be smaller than the refractive index in the major-axis direction and greater than the refractive index in the minor-axis direction, but embodiments of the present disclosure are not necessarily limited hereto. For example, the intermediate refractive indices may also be smaller than the refractive index in the minor-axis direction and greater than the refractive index in the major-axis direction.

In an embodiment, the major-axis direction of the lenses 231 may be parallel to the second direction (e.g., the Y-axis direction), and the minor-axis direction of the lenses 231 may be parallel to the first direction (e.g., the X-axis direction). In some cases, the refractive index of the filler layer 240 may be equal to the refractive index of the lenses 231 in the minor-axis direction and may be smaller than the refractive index of the lenses 231 in the major-axis direction, but embodiments of the present disclosure are not necessarily limited hereto.

Referring to FIG. 6, light passing through the driving liquid crystals 254 may have a path PDX in the first linear polarization direction, and the first linear polarization direction may be coincident with or parallel to the first direction (e.g., the X-axis direction). Therefore, the light passing through the driving liquid crystals 254 may experience the refractive index of the lenses 231 in the minor-axis direction. Since the refractive index of the lenses 231 in the minor-axis direction is equal to the refractive index of the filler layer 240, the light passing through the driving liquid crystals 254 may travel straight without being refracted at an interface between the lenses 231 and the filler layer 240. A 2D image may be displayed from the second type of light field display by the un-refracted light.

Referring to FIG. 7, light passing through the driving liquid crystals 254 may have a path PDY in the second linear polarization direction, and the second linear polarization direction may be coincident with or parallel to the second direction (e.g., the Y-axis direction). Therefore, the light passing through the driving liquid crystals 254 may experience the refractive index of the lenses 231 in the major-axis direction. Since the refractive index of the lenses 231 in the major-axis direction is greater than the refractive index of the filler layer 240, the light passing through the driving liquid crystals 254 may be refracted at an interface between the lenses 231 and the filler layer 240. A 3D image may be displayed from the second type of light field display by the refracted light. The refracted light may travel to a first view area V1, a second view area V2, and a third view area V3 according to mapped viewing angles.

Referring again to FIGS. 6 and 7, the black matrix 235 may be disposed between the lenses 231. The black matrix 235 may include a light absorbing material that absorbs light. For example, the light absorbing material may be a black dye or a black pigment. The black matrix 235 may absorb light between the lenses 231. Accordingly, the black matrix 235 may prevent crosstalk from occurring due to diffraction of light at the boundary between the lenses 231.

In a plan view, a length of a lower surface of the black matrix 235 measured along the first direction (e.g., the x-direction) may be greater than a length of an upper surface of the black matrix 235 measured along the first direction. Side surfaces of the black matrix 235 may be formed as planes. For example, the black matrix 235 may be formed with a trapezoidal shape.

The light reflectors 236 may be disposed between the lenses 231 and the black matrix 235 to reflect light traveling from the emission areas EA1, EA2 and EA3 toward the black matrix 235.

The filler layer 240 may be disposed on the lenses 231, the black matrix 235, and the light reflectors 236. The second base substrate 220 may be positioned on the filler layer 240.

The filler layer 240 may include a transparent material that can transmit light. For example, the filler layer 240 may include an isotropic polymer material.

As described above, the refractive index of the filler layer 240 may be equal to the refractive index of the lenses 231 in the minor-axis direction. The refractive index of the filler layer 240 may be smaller than the refractive index of the lenses 231 in the major-axis direction. Accordingly, light passing through the lenses 231 may or might not be refracted at the interfaces.

Referring to FIGS. 4 and 5, in the first type of light field display, the display panel may include a substrate SUB, a thin-film transistor layer TFTL, a light emitting element layer EML, and an encapsulation layer TFE. Elements having substantially the same function as those of the second type of light field display described above are indicated by like reference numerals, and a repeated description might not be described.

A polarizing member 257 may be disposed between the display panel and a first base substrate 210. Light emitted from the display panel may vibrate in all directions. The polarizing member 257 may transmit only light vibrating in a specific direction among the light emitted from the display panel and may block the rest. In an embodiment, the polarizing member 257 may transmit only light having a path PDX in the first linear polarization direction among the light emitted from the display panel, but embodiments of the present disclosure are not necessarily limited hereto.

A third driving electrode 232 may be disposed between the first base substrate 210 and a second base substrate 220, and a fourth driving electrode 233 may be disposed between the first base substrate 210 and the third driving electrode 232. An optical lens, which includes lenses 231, a black matrix 235 and light reflectors 236, may be disposed between the third driving electrode 232 and the fourth driving electrode 233. A filler layer 240 may be located on the optical lens, but as described above, the vertical relationship between them is not necessarily limited hereto.

Voltages may be applied to the third driving electrode 232 and the fourth driving electrode 233, and the lenses 231 may include liquid crystals which are birefringent materials. The arrangement of the liquid crystals in the lenses 231 may vary according to a difference between the voltages applied to the third driving electrode 232 and the fourth driving electrode 233.

Referring to FIG. 4, the difference between the voltage applied to the third driving electrode 232 and the voltage applied to the fourth driving electrode 233 during a 2D image display period may be equal to or greater than a selected value. Light passing through the display panel may have a path PDX in the first linear polarization direction. The first linear polarization direction may be coincident with or parallel to the minor-axis direction of the liquid crystals in the lenses 231. The light may pass through the liquid crystals while experiencing a refractive index in the liquid crystals in the minor-axis direction. Since the refractive index in the minor-axis direction is equal to a refractive index of the filler layer 240, the light might not be refracted at interfaces. A 2D image may be displayed from the first type of light field display by the un-refracted light.

Referring to FIG. 5, the difference between the voltage applied to the third driving electrode 232 and the voltage applied to the fourth driving electrode 233 during a 3D image display period may be less than the selected value. Light passing through the display panel may have a path PDX in the first linear polarization direction. The first linear polarization direction may be coincident with or parallel to the major-axis direction of the liquid crystals in the lenses 231. The light may pass through the liquid crystals while experiencing a refractive index of the liquid crystals in the major-axis direction. Since the refractive index in the major-axis direction is greater than the refractive index of the filler layer 240, the light may be refracted at the interfaces. A 3D image may be displayed from the first type of light field display by the refracted light. The refracted light may travel to a first view area V1, a second view area V2, and a third view area V3 according to mapped viewing angles.

In the above description, the refractive index of the filler layer 240 may be equal to the refractive index of the lenses 231 in the minor-axis direction and may be smaller than the refractive index in the major-axis direction. In some cases, the linear polarization directions may be specified in the first and second types of light field displays. In some cases, the first type of light field display, a 2D image is displayed when voltages are applied to the third driving electrode 232 and the fourth driving electrode 233, and a 3D image is displayed when no voltage is applied. In some cases, in the second type of light field display, a 2D image is displayed when no voltage is applied to the first driving electrode 251 and the second driving electrode 252, and a 3D image is displayed when voltages are applied.

It should be noted that this is merely an example used for ease and consistency of description. Variables, such as a refractive index range based on the birefringence characteristics of liquid crystals, the refractive index value of the filler layer, and the linear polarization direction of light passing through an individual element may be modified within the scope of practice of those of ordinary skill in the art.

However, in the first type of light field display, the major-axis direction and the minor-axis direction of the liquid crystals in the lenses 231 may be directly modified. In the second type of light field display, the linear polarization direction of light passing through the display panel may be directly modified.

The switchable configuration of the first and second types of light field displays enables the display system of the present disclosure to dynamically adapt to 2D or 3D content without the need for physical realignment or additional hardware layers. This flexibility enables display devices to optimize power consumption, display resolution, and user experience based on the content being viewed. For example, when displaying high-resolution 2D text or graphics, the display device may operate in a 2D mode with un-refracted light paths, thereby preserving image quality. Additionally, for enhanced visual content such as 3D movies, the display device can switch to 3D mode with directional refraction for stereoscopic depth perception.

The use of polarization direction control in the second type of light field display provides an electrical method of switching between image modes without mechanically altering the lens system. This method not only reduces the complexity and thickness of the optical module but also increases reliability and switching speed, enabling real-time toggling between 2D and 3D modes.

In 3D display mode, as shown in FIGS. 5 and 7, the display device guides light toward specific view areas (V1, V2, V3) corresponding to different eye positions. Each view area receives light encoded with different image data (e.g., left-eye vs. right-eye), enabling binocular disparity. This view mapping mechanism enhances features and functionalities of the stereoscopic perception.

The display device further includes the black matrix 235 and light reflectors 236, which enhances image contrast and optical efficiency by absorbing or redirecting stray light. Embodiments of the present disclosure minimize leakage and optical crosstalk between adjacent lenses, which can otherwise degrade 3D image quality. Accordingly, clean view separation and high image quality can be maintained.

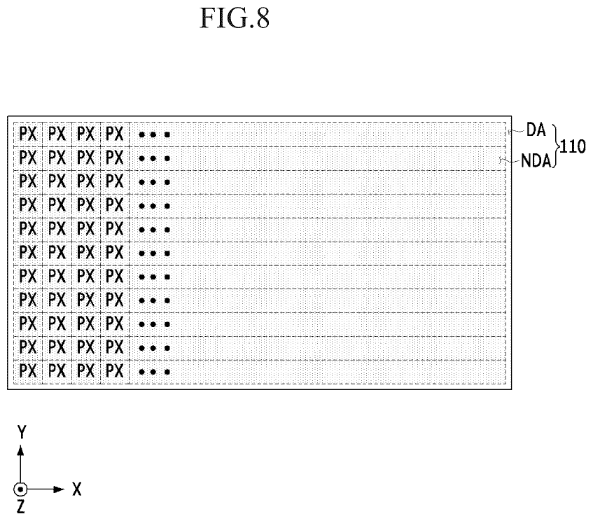

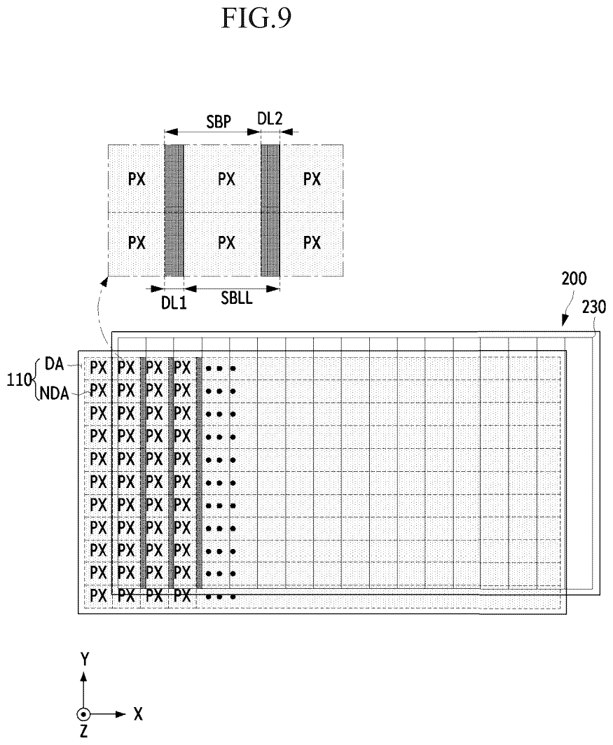

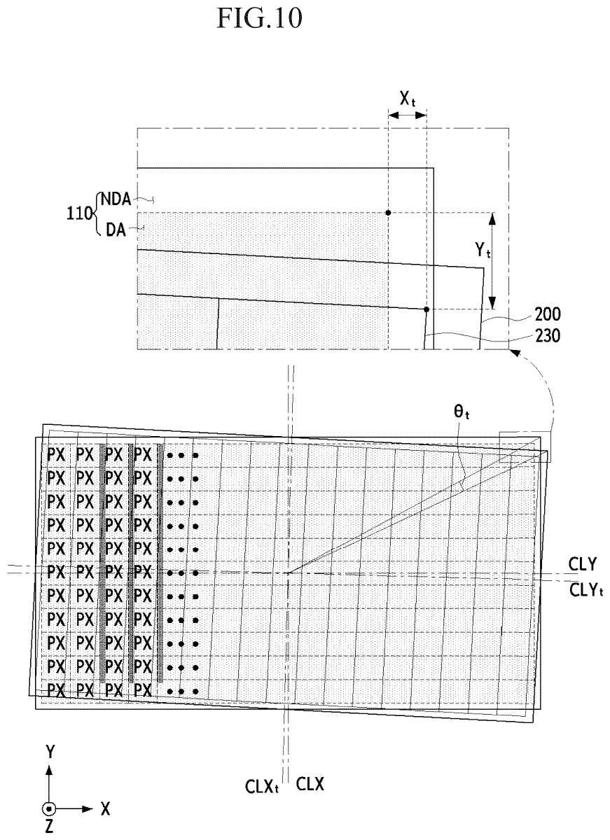

FIG. 8 is a plan view of a display panel. FIG. 9 illustrates an example of a moire phenomenon occurrence due to an optical lens disposed on the display panel. FIG. 10 illustrates an example of tilting the optical lens disposed on the display panel to prevent the moire phenomenon.

Referring to FIG. 8, a display panel 110 may include a display area DA and a non-display area NDA surrounding the display area DA. A plurality of pixels PX may be disposed in the display area DA. Each of the pixels PX may include a first subpixel that emits a first color, a second subpixel that emits a second color, and a third subpixel that emits a third color. The first color, the second color, and the third color may each include red, green, and blue such that the first, second, and third colors do not overlap with each other. For example, the first color may be red, the second color may be green, and the third color may be blue, but embodiments of the present disclosure are not necessarily limited hereto.

Referring to FIG. 9, a lens assembly 200 may be disposed on the display panel 110. The lens assembly 200 may include an optical lens 230.

Referring to the enlarged view, a plurality of pixels PX may be arranged at first intervals SBP, and a plurality of lenses in the optical lens 230 of the lens assembly 200 may be arranged at second intervals SBLL. The first intervals SBP may be the same as or different from the second intervals SBLL. In some embodiments, the first intervals SBP and the second intervals SBLL are offset from each other by a predetermined distance to induce or control moiré interference effects.

For example, a boundary between the pixels PX arranged at the first intervals SBP may be offset from a boundary between the lenses arranged at the second intervals SBLL. For example, the first intervals SBP may be different from the second intervals SBLL. For example, since the boundary between the pixels PX and the boundary between the lenses do not overlap each other, a plurality of gaps having different sizes can occur. For example, since the boundary between the pixels PX and the boundary between the lenses do not overlap each other (e.g., the boundary between the pixels PX and the boundary between the lenses are offset by a predetermined distance), a first boundary gap DL1 and a second boundary gap DL2 may be formed. The variation in gap sizes contributes to periodic visual interference patterns, which may result in a moiré effect when viewed from specific angles or under certain lighting conditions

The first boundary gap DL1 and the second boundary gap DL2 may be smaller than the first intervals SBP and the second intervals SBLL. The interaction between patterns due to the first boundary gap DL1 and the second boundary gap DL2 may induce a moire phenomenon. The moire phenomenon may occur due to the interaction of a plurality of regular patterns when the regular patterns overlap each other. The moire phenomenon in the process of attaching the lens assembly 200 to the display panel 110 may deteriorate the display quality of a display device.

Referring to FIG. 10, to prevent the deterioration or degradation in the display quality due to the moire phenomenon, the lens assembly 200 may be attached onto the display panel 110 with a tilt at a moire-minimizing angle. This tilt adjusts the relative orientation between the pixel grid and the lens array, thereby preventing the degradation in the display device.

During a manufacturing process, a moire-minimizing angle at which the moire phenomenon is minimized can be determined by tilting the lens assembly 200. In the conventional art, the lens assembly 200 tilted at this angle may be attached to a display device.

For example, a first central axis CLY extending from the display panel 110 in the first direction and a second central axis CLX extending in the second direction intersecting the first direction may be defined. For example, the first direction may be the X-axis direction, and the second direction may be the Y-axis direction. The first direction and the second direction may be cross (or perpendicular to) each other, but embodiments of the present disclosure are not necessarily limited hereto. In some cases, a third central axis CLYₜ extending from the lens assembly 200 in the first direction and a fourth central axis CLXₜ extending in the second direction may be defined.

In a case where a moire-minimizing angle that can minimize the moire phenomenon is derived, a distance between a reference point on the display panel 110 and a reference point on the lens assembly 200 is calculated to attach the lens assembly 200 to the display panel 110 by tilting the lens assembly 200 at a predetermined angle. The distance between the reference point on the display panel 110 and the reference point on the lens assembly 200 can be segmented into a first distance Xₜ in the first direction (e.g., the X-axis direction) and a second distance Yₜ in the second direction (e.g., the Y-axis direction). The first distance Xₜ and the second distance Yₜ may be computed by applying trigonometric relationships such as cosines, sines, and tangents to the predetermined angle and a distance between a reference point and a center. In some cases, the moire-minimizing angle that minimizes the moire phenomenon has a very small value. Therefore, for accurate attachment, the distance between the reference points, which is obtained from the moire-minimizing angle, is used.

However, even using the distance between the reference points to compute the moire-minimizing angle, attaching the display panel 110 and the lens assembly 200 to each other using the first distance Xₜ and the second distance Yₜ between the reference points may result in inaccuracies in the manufacturing process, and errors may occur in the attachment process.

Therefore, the present disclosure provide alignment marks that can be used to accurately tilt and attach the lens assembly 200 using a moire-minimizing angle that can minimize the moire phenomenon.

A plurality of panel alignment marks attached or formed on the display module 100 and an optical alignment mark attached or formed on the lens assembly 200 may be attached or formed on the display panel 110 and the lens assembly 200, respectively, at predetermined intervals based on the sizes of the display panel 110 and the lens assembly 200. The alignment marks may be used not only to set the moiré-minimizing angle, but also to guide lateral positioning between the display panel 110 and the lens assembly 200 with sub-pixel precision.

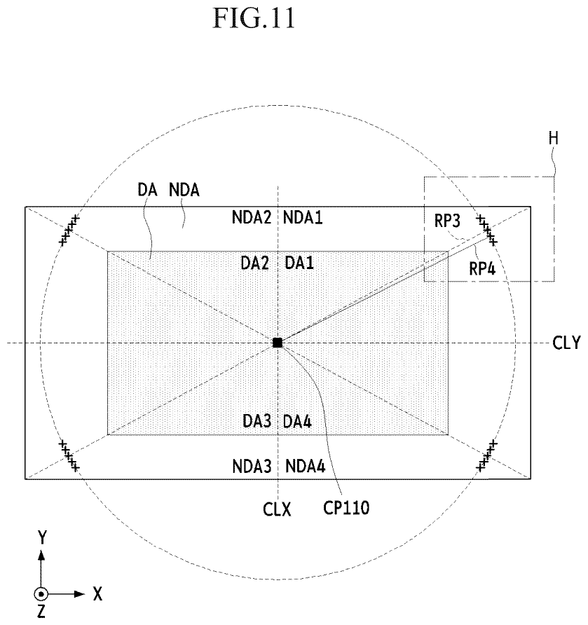

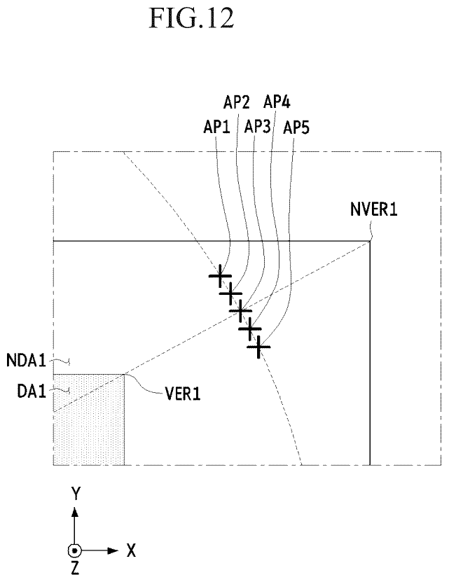

FIG. 11 is a plan view of a display panel 110 according to an embodiment of the present disclosure. FIG. 12 is an enlarged view of portion H of FIG. 11.

As used herein, radial distance refers to the linear distance from a center point (e.g., a geometric center of a display panel or lens assembly) to another point located along an imaginary radius extending outward from the center. For example, alignment marks are positioned at a radial distance when the alignment marks are spaced apart from the center point.

Arc length refers to the curved distance measured along the circumference of a circle between two points, such as between two alignment marks that are equidistant from a center. The arc length corresponds to the angular separation between the two alignment marks around the center.

Referring to FIGS. 11 and 12, a first central axis CLY extending in the first direction (e.g., the X-axis direction) from the display panel 110 and a second central axis CLX extending in the second direction (e.g., the Y-axis direction) may be established. An intersection point of the first central axis CLY and the second central axis CLX may be a display panel center CP110, which is a center of the display panel 110 and a center of gravity of the display panel 110. Each of the first central axis CLY, the second central axis CLX, and the display panel center CP110 may be a virtual straight line or point derived from the display panel 110. The display panel center CP110 serves as the origin for positioning alignment marks and calculating radial distances to maintain geometric symmetry across one or more panel regions.

The display panel 110 may include a first display panel portion (e.g., first display area DA1 and a first non-display area NDA1), a second display panel portion (e.g., second display area DA2 and a second non-display area NDA2), a third display panel portion (e.g., third display area DA3 and a third non-display area NDA3), and a fourth display panel portion (e.g., fourth display area DA4 and a fourth non-display area NDA4). The first display panel portion (DA1, NDA1) may include a first display area DA1 and a first non-display area NDA1. The second display panel portion (DA2, NDA2) may include a second display area DA2 and a second non-display area NDA2. The third display panel portion (DA3, NDA3) may include a third display area DA3 and a third non-display area NDA3. The fourth display panel portion (DA4, NDA4) may include a fourth display area DA4 and a fourth non-display area NDA4.

The second display panel portion (DA2, NDA2) may be located on a side of the first display panel portion (DA1, NDA1). For example, the second display area DA2 may be located on a side of the first display area DA1, and the second non-display area NDA2 may be located on a side of the first non-display area NDA1. A straight line along a side where the first display panel portion (DA1, NDA1) and the second display panel portion (DA2, NDA2) meet may be parallel to the second direction (e.g., the Y-axis direction).

The third display panel portion (DA3, NDA3) may be located on a side of the second display panel portion (DA2, NDA2). For example, the third display area DA3 may be located on a side of the second display area DA2, and the third non-display area NDA3 may be located on a side of the second non-display area NDA2. A straight line along a side where the second display panel portion (DA2, NDA2) and the third display panel portion (DA3, NDA3) meet may be parallel to the first direction (e.g., the X-axis direction).

The first straight line along the side where the first display panel portion (DA1, NDA1) and the second display panel portion (DA2, NDA2) meet and the second straight line along the side where the second display panel portion (DA2, NDA2) and the third display panel portion (DA3, NDA3) meet may intersect at the display panel center CP110.

The fourth display panel portion (DA4, NDA4) may be located on a side of the first display panel portion (DA1, NDA1). For example, the fourth display area DA4 may be located on a side of the first display area DA1, and the fourth non-display area NDA4 may be located on a side of the first non-display area NDA1. A straight line along a side where the first display panel portion (DA1, NDA1) and the first display panel portion (DA1, NDA1) meet may be parallel to the first direction (e.g., the X-axis direction).

The straight line defined by the side where the first display panel portion (DA1, NDA1) and the second display panel portion (DA2, NDA2) meet and the straight line along the side where the first display panel portion (DA1, NDA1) and the fourth display panel portion (DA4, NDA4) meet may intersect at the display panel center CP110.

The fourth display panel portion (DA4, NDA4) may be located on a side of the third display panel portion (DA3, NDA3). For example, the fourth display area DA4 may be located on a side of the third display area DA3, and the fourth non-display area NDA4 may be located on a side of the third non-display area NDA3. A straight line along a side where the third display panel portion (DA3, NDA3) and the fourth display panel portion (DA4, NDA4) meet may be parallel to the second direction (e.g., the Y-axis direction).

The straight line along the side where the third display panel portion (DA3, NDA3) and the fourth display panel portion (DA4, NDA4) meet may coincide with the straight line along the side where the first display panel portion (DA1, NDA1) and the second display panel portion (DA2, NDA2) meet and may extend in the second direction (e.g., the Y-axis direction). In some cases, the straight line along the side where the second display panel portion (DA2, NDA2) and the third display panel portion (DA3, NDA3) meet may coincide with the straight line along the side where the first display panel portion (DA1, NDA1) and the fourth display panel portion (DA4, NDA4) meet and may extend in the first direction (e.g., the X-axis direction). These lines may form an intersection point at the display panel center CP110.

For example, each of the first display panel portion (DA1, NDA1) and the second display panel portion (DA2, NDA2) may include a plurality of panel alignment marks. Each of the third display panel portion (DA3, NDA3) and the fourth display panel portion (DA4, NDA4) may also include a plurality of panel alignment marks. The panel alignment marks may be symmetrically distributed within the non-display areas of each display panel portion, relative to a center point CP110. As the number of panel alignment marks increases, the accuracy and precision of attachment of a lens assembly 200 may increase. By forming a plurality of panel alignment marks in each display panel portion, the moire phenomenon of a display device can be reduced and the display quality of the display device can be enhanced.

For example, the first display panel portion (DA1, NDA1) may include a first panel alignment mark AP1, a second panel alignment mark AP2, a third panel alignment mark AP3, a fourth panel alignment mark AP4, and a fifth panel alignment mark AP5. In some cases, the first through fifth panel alignment marks AP1 through AP5 may be arranged with respect to a reference axis or at equal angular intervals from a central point CP110.

A center of the third panel alignment mark AP3 may be located on a straight line connecting the display panel center CP110 and a first panel outer vertex NVER1. The straight line connecting the display panel center CP110 and the first panel outer vertex NVER1 may coincide with a straight line connecting a first panel inner vertex VER1 and the first panel outer vertex NVER1. In some cases, the first panel inner vertex VER1 may be positioned at a boundary of the display area DA1, and the first panel outer vertex NVER1 may be positioned at a boundary of the non-display area NDA1.

Distances between the first panel alignment mark AP1, the second panel alignment mark AP2, the third panel alignment mark AP3, the fourth panel alignment mark AP4 and the fifth panel alignment mark AP5, which are located in the first display panel portion (DA1, NDA1), and the display panel center CP110 are equal. In an embodiment, the first panel alignment mark AP1, the second panel alignment mark AP2, the third panel alignment mark AP3, the fourth panel alignment mark AP4, and the fifth panel alignment mark AP5 may be located on the circumference of a circle having the display panel center CP110 as the center. The radius of the circle may be substantially equal to the distance between the third panel alignment mark AP3 and the display panel center CP110. The circular arrangement enables angularly symmetric placement of the alignment marks, thereby facilitating precise rotational positioning of the lens assembly 200 during the attachment process.

The first panel alignment mark AP1, the second panel alignment mark AP2, the third panel alignment mark AP3, the fourth panel alignment mark AP4, and the fifth panel alignment mark AP5 may also be formed in the second display panel portion (DA2, NDA2) through the fourth display panel portion (DA4, NDA4). In the second display panel portion (DA2, NDA2) through the fourth display panel portion (DA4, NDA4), the distances between the first panel alignment mark AP1, the second panel alignment mark AP2, the third panel alignment mark AP3, the fourth panel alignment mark AP4 and the fifth panel alignment mark AP5 each with respect to the display panel center CP110 are equal (e.g., RP=RP3=RP4). In some cases, the distance between the first panel alignment mark AP1, which is located in the first display panel portion (DA1, NDA1), and the display panel center CP110, the distance between the first panel alignment mark AP1, which is located in the second display panel portion (DA2, NDA2), and the display panel center CP110, the distance between the first panel alignment mark AP1, which is located in the third display panel portion (DA3, NDA3), and the display panel center CP110, and the distance between the first panel alignment mark AP1, which is located in the fourth display panel portion (DA4, NDA4), and the display panel center CP110 are equal. These alignment marks may be located on the circumference of a circle having the display panel center CP110 as the center. The radius of the circle may be substantially equal to the distance between the third panel alignment mark AP3 and the display panel center CP110.

In each of the first display panel portion (DA1, NDA1), the second display panel portion (DA2, NDA2), the third display panel portion (DA3, NDA3), and the fourth display panel portion (DA4, NDA4), the first panel alignment mark AP1, the second panel alignment mark AP2, the third panel alignment mark AP3, the fourth panel alignment mark AP4, and the fifth panel alignment mark AP5 may be arranged at equal intervals. Since the first panel alignment mark AP1, the second panel alignment mark AP2, the third panel alignment mark AP3, the fourth panel alignment mark AP4, and the fifth panel alignment mark AP5 are located on the circumference of a circle having the display panel center CP110 as its center, a distance between the first panel alignment mark AP1 and the second panel alignment mark AP2, a distance between the second panel alignment mark AP2 and the third panel alignment mark AP3, a distance between the third panel alignment mark AP3 and the fourth panel alignment mark AP4, and a distance between the fourth panel alignment mark AP4 and the fifth panel alignment mark AP5 are equal.

For example, a straight line connecting the first panel alignment mark AP1 and the display panel center CP110 and a straight line connecting the second panel alignment mark AP2 and the display panel center CP110 may form a first angle. The straight line connecting the second panel alignment mark AP2 and the display panel center CP110 and a straight line connecting the third panel alignment mark AP3 and the display panel center CP110 may form the first angle. The straight line connecting the third panel alignment mark AP3 and the display panel center CP110 and a straight line connecting the fourth panel alignment mark AP4 and the display panel center CP110 may form the first angle. The straight line connecting the fourth panel alignment mark AP4 and the display panel center CP110 and a straight line connecting the fifth panel alignment mark AP5 and the display panel center CP110 may form the first angle.

The first angle may be a predetermined angle as described above and may be an angle that minimizes the moire phenomenon when the lens assembly 200 is attached. The first angle may be an acute angle.

The second panel alignment mark AP2 may be obtained by rotating the first panel alignment mark AP1 clockwise by the first angle on the circumference of a circle having the display panel center CP110 as the center. A straight line resulting from rotating the straight line connecting the first panel alignment mark AP1 and the display panel center CP110 clockwise by the first angle around the display panel center CP110 as a reference point may coincide with the straight line connecting the second panel alignment mark AP2 and the display panel center CP110. In some cases, the consistent radial and angular distribution of the alignment marks facilitates pattern recognition and alignment control. In some cases, the display panel center CP110 may be a virtual geometric point derived from the symmetry of the display panel and might not correspond to a physical mark.

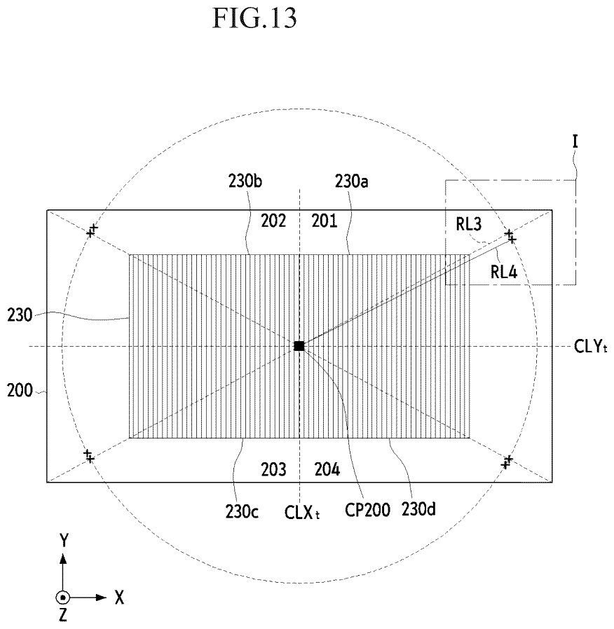

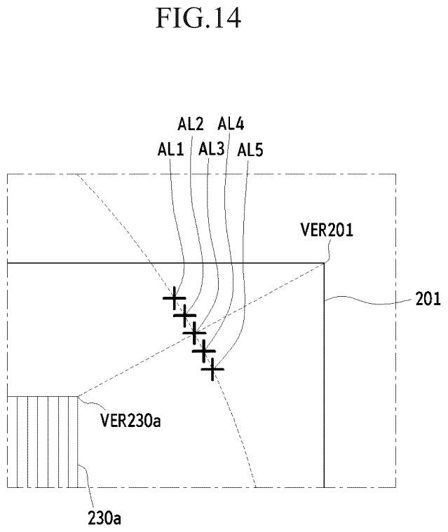

FIG. 13 is a plan view of an optical lens according to an embodiment of the present disclosure. FIG. 14 is an enlarged view of portion I of FIG. 13.

Referring to FIGS. 13 and 14, a third central axis CLYₜ extending in the first direction (e.g., the X-axis direction) from a lens assembly 200 and a fourth central axis CLXₜ extending in the second direction (e.g., the Y-axis direction) may be established. An intersection point of the third central axis CLYₜ and the fourth central axis CLXₜ may be a lens assembly center CP200, which is a center of the lens assembly 200 and a center of gravity of the lens assembly 200. Each of the third central axis CLYₜ, the fourth central axis CLXₜ, and the lens assembly center CP200 may be a virtual straight line or point derived from the lens assembly 200. The third and fourth central axes are arranged to correspond to the first and second central axes CLYₜ and CLXₜ of the display panel 110 for precise alignment between the lens assembly 200 and the display panel 110.

The lens assembly 200 may include a first lens assembly portion 201, a second lens assembly portion 202, a third lens assembly portion 203, and a fourth lens assembly portion 204. The first lens assembly portion 201 may include a first optical lens portion 230a. The second lens assembly portion 202 may include a second optical lens portion 230b. The third lens assembly portion 203 may include a third optical lens portion 230c. The fourth lens assembly portion 204 may include a fourth optical lens portion 230d.

The second lens assembly portion 202 may be located on a side of the first lens assembly portion 201. For example, the second optical lens portion 230b may be located on a side of the first optical lens portion 230a. A first straight line along a side where the first lens assembly portion 201 and the second lens assembly portion 202 meet may be parallel to the second direction (e.g., the Y-axis direction).

The third lens assembly portion 203 may be located on a side of the second lens assembly portion 202. For example, the third optical lens portion 230c may be located on a side of the second optical lens portion 230b. A second straight line along a side where the second lens assembly portion 202 and the third lens assembly portion 203 meet may be parallel to the first direction (e.g., the X-axis direction).

The first straight line along the side where the first lens assembly portion 201 and the second lens assembly portion 202 meet and the second straight line along the side where the second lens assembly portion 202 and the third lens assembly portion 203 meet may intersect at the lens assembly center CP200.

The fourth lens assembly portion 204 may be located on a side of the first lens assembly portion 201. For example, the fourth optical lens portion 230d may be located on a side of the first optical lens portion 230a. A third straight line along a side where the fourth lens assembly portion 204 and the first lens assembly portion 201 meet may be parallel to the first direction (e.g., the X-axis direction).

The first straight line along the side where the first lens assembly portion 201 and the second lens assembly portion 202 meet and the third straight line along the side where the first lens assembly portion 201 and the fourth lens assembly portion 204 meet may intersect at the lens assembly center CP200.

The fourth lens assembly portion 204 may be located on a side of the third lens assembly portion 203. For example, the fourth optical lens portion 230d may be located on a side of the third optical lens portion 230c. A fourth straight line along a side where the third lens assembly portion 203 and the fourth lens assembly portion 204 meet may be parallel to the second direction (e.g., the Y-axis direction).

The fourth straight line along the side where the third lens assembly portion 203 and the fourth lens assembly portion 204 meet may coincide with the first straight line along the side where the first lens assembly portion 201 and the second lens assembly portion 202 meet and may extend in the second direction (e.g., the Y-axis direction). In some cases, the second straight line along the side where the second lens assembly portion 202 and the third lens assembly portion 203 meet may coincide with the third straight line along the side where the first lens assembly portion 201 and the fourth lens assembly portion 204 meet and may extend in the first direction (e.g., the X-axis direction). These lines may intersect at the lens assembly center CP200.

For example, each of the first lens assembly portion 201 and the second lens assembly portion 202 may include a plurality of optical alignment marks. Each of the third lens assembly portion 203 and the fourth lens assembly portion 204 may also include a plurality of optical alignment marks. As the number of optical alignment marks increases, the accuracy and precision of attachment of the lens assembly 200 may increase. By forming a plurality of optical alignment marks in each lens assembly portion, the moire phenomenon of a display device can be reduced and the display quality of the display device can be enhanced.

For example, the first lens assembly portion 201 may include a first optical alignment mark AL1, a second optical alignment mark AL2, a third optical alignment mark AL3, a fourth optical alignment mark AL4, and a fifth optical alignment mark AL5. These optical alignment marks may be arranged radially and symmetrically with respect to the lens assembly center CP200.

A center of the third optical alignment mark AL3 may be located on a straight line connecting the lens assembly center CP200 and a first lens assembly outer vertex VER201. The straight line connecting the lens assembly center CP200 and the first lens assembly outer vertex VER201 may coincide with a straight line connecting a first lens assembly inner vertex VER230a and the first lens assembly outer vertex VER201. Each of the optical alignment marks AL1 through AL5 is located on the circumference of a circle centered at the lens assembly center CP200, and the radius of the circle corresponds to the distance between CP200 and AL3. This circular arrangement may geometrically mirror the panel alignment structure centered at CP110, thereby facilitating precise alignment between the lens assembly 200 and the display panel 110.

Distances between the first optical alignment mark AL1, the second optical alignment mark AL2, the third optical alignment mark AL3, the fourth optical alignment mark AL4 and the fifth optical alignment mark AL5, which are located in the first lens assembly portion 201, and the lens assembly center CP200 may be equal (e.g., RL=RL3=RL4). In an embodiment, the first optical alignment mark AL1, the second optical alignment mark AL2, the third optical alignment mark AL3, the fourth optical alignment mark AL4, and the fifth optical alignment mark AL5 may be located on the circumference of a circle having the lens assembly center CP200 as the center. The radius of the circle may be substantially equal to the distance between the third optical alignment mark AL3 and the lens assembly center CP200.

The first optical alignment mark AL1, the second optical alignment mark AL2, the third optical alignment mark AL3, the fourth optical alignment mark AL4, and the fifth optical alignment mark AL5 may also be formed in the second lens assembly portion 202 through the fourth lens assembly portion 204. In the second lens assembly portion 202 through the fourth lens assembly portion 204, the distances between the first optical alignment mark AL1, the second optical alignment mark AL2, the third optical alignment mark AL3, the fourth optical alignment mark AL4 and the fifth optical alignment mark AL5 and the lens assembly center CP200 may be equal. In some cases, a distance between the first optical alignment mark AL1, which is located in the first lens assembly portion 201, and the lens assembly center CP200, a distance between the first optical alignment mark AL1, which is located in the second lens assembly portion 202, and the lens assembly center CP200, a distance between the first optical alignment mark AL1, which is located in the third lens assembly portion 203, and the lens assembly center CP200, and a distance between the first optical alignment mark AL1, which is located in the fourth lens assembly portion 204, and the lens assembly center CP200 may be equal to one another. These alignment marks may be located on the circumference of a circle having the lens assembly center CP200 as the center. The radius of the circle may be substantially equal to the distance between the third optical alignment mark AL3 and the lens assembly center CP200. The radial symmetry of these alignment marks across the four lens assembly portions facilitates consistent alignment with the panel alignment marks centered at CP110.

In each of the first lens assembly portion 201, the second lens assembly portion 202, the third lens assembly portion 203, and the fourth lens assembly portion 204, the first optical alignment mark AL1, the second optical alignment mark AL2, the third optical alignment mark AL3, the fourth optical alignment mark AL4, and the fifth optical alignment mark AL5 may be arranged at equal intervals. Since the first optical alignment mark AL1, the second optical alignment mark AL2, the third optical alignment mark AL3, the fourth optical alignment mark AL4, and the fifth optical alignment mark AL5 are located on the circumference of a circle having the lens assembly center CP200 as the center, a distance between the first optical alignment mark AL1 and the second optical alignment mark AL2, a distance between the second optical alignment mark AL2 and the third optical alignment mark AL3, a distance between the third optical alignment mark AL3 and the fourth optical alignment mark AL4, and a distance between the fourth optical alignment mark AL4 and the fifth optical alignment mark AL5 may be equal. This equal spacing represents a constant angular interval between adjacent alignment marks, enabling uniform angular calibration during alignment of the lens assembly 200 to the display panel 110.

For example, a first straight line connecting the first optical alignment mark AL1 and the lens assembly center CP200 and a second straight line connecting the second optical alignment mark AL2 and the lens assembly center CP200 may form a first angle. The second straight line connecting the second optical alignment mark AL2 and the lens assembly center CP200 and a third straight line connecting the third optical alignment mark AL3 and the lens assembly center CP200 may form the first angle. The third straight line connecting the third optical alignment mark AL3 and the lens assembly center CP200 and a fourth straight line connecting the fourth optical alignment mark AL4 and the lens assembly center CP200 may form the first angle. The fourth straight line connecting the fourth optical alignment mark AL4 and the lens assembly center CP200 and a fifth straight line connecting the fifth optical alignment mark AL5 and the lens assembly center CP200 may form the first angle. Each pair of adjacent straight lines has an equal angular interval about the lens assembly center CP200, supporting uniform rotational positioning of the lens assembly 200.

The first angle may be a predetermined angle as described above and may be an angle that minimizes the moire phenomenon when the lens assembly 200 is attached. The first angle may be an acute angle.

The second optical alignment mark AL2 may be obtained by rotating the first optical alignment mark AL1 clockwise by the first angle on the circumference of a circle having the lens assembly center CP200 as the center. A straight line resulting from rotating the straight line connecting the first optical alignment mark AL1 and the lens assembly center CP200 clockwise by the first angle around the lens assembly center CP200 may coincide with the straight line connecting the second optical alignment mark AL2 and the lens assembly center CP200.

This radial rotation and symmetric placement of optical alignment marks correspond to the arrangement of panel alignment marks around the display panel center CP110. Accordingly, when the lens assembly 200 is placed onto the display panel 110 with an angular offset equal to the first angle, the optical alignment marks can align with the panel alignment marks, thereby achieving high-precision overlay alignment. This configuration ensures that the moire-minimizing angle is maintained during assembly.

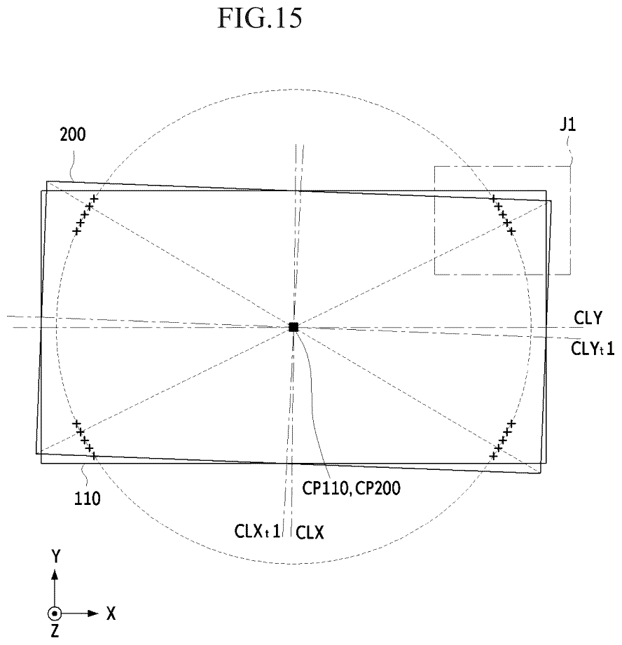

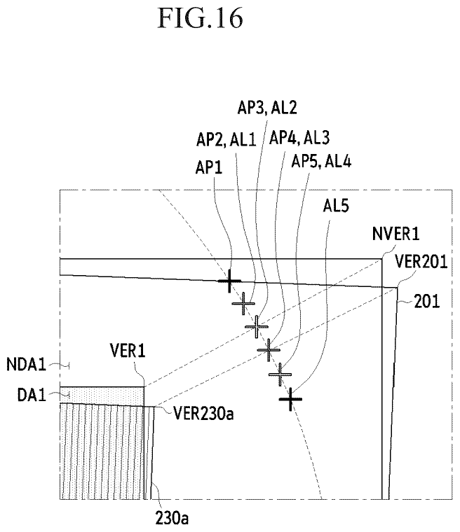

FIG. 15 is a plan view of a display device according to a first embodiment of the present disclosure. FIG. 16 is an enlarged view of portion J1 of FIG. 15.

Referring to FIGS. 15 and 16, when a lens assembly 200 is placed on a display panel 110, a first central axis CLY and a third central axis CLYₜ1 may form a first angle with each other. A second central axis CLX and a fourth central axis CLXₜ1 may also form the first angle with each other. A display panel center CP110 and a lens assembly center CP200 may overlap each other in a thickness direction of the display panel 110.

At least a part of a first lens assembly portion 201 may overlap at least a part of a first display panel portion (e.g., a first display area DA1 and a first non-display area NDA1) in the thickness direction of the display panel 110. In some cases, at least a part of a first optical lens portion 230a may overlap at least a part of a first display area DA1 in the thickness direction of the display panel 110.

In an embodiment, a second panel alignment mark AP2 may overlap a first optical alignment mark AL1 in the thickness direction, a third panel alignment mark AP3 may overlap a second optical alignment mark AL2 in the thickness direction, a fourth panel alignment mark AP4 may overlap a third optical alignment mark AL3 in the thickness direction, and a fifth panel alignment mark AP5 may overlap a fourth optical alignment mark AL4 in the thickness direction. In some cases, the vertical overlap between corresponding alignment marks (e.g., the optical alignment marks and the corresponding panel align marks) facilitates accurate positioning of the lens assembly 200 relative to the display panel 110.

The second optical alignment mark AL2 may be located on a straight line connecting a first panel inner vertex VER1 and a first panel outer vertex NVER1. The fourth panel alignment mark AP4 may be located on a straight line connecting a first lens assembly inner vertex VER230a and a first lens assembly outer vertex VER201.

In an embodiment, as the first angle decreases, the number of alignment marks arranged on the display panel 110 and the lens assembly 200 may increase. Therefore, an angle that reduces the moire phenomenon can be adjusted more precisely. For example, if the lens assembly 200 is rotated clockwise by the first angle around the display panel center CP110 (or the lens assembly center CP200), the number of alignment marks overlapping each other may also increase.

However, if the lens assembly 200 is rotated clockwise by twice the first angle instead of the first angle, the number of alignment marks overlapping each other may relatively decrease. In some cases, as the alignment marks are arranged radially with respect to the central axis and spaced at regular angular intervals, incremental rotation by the first angle facilitates repeatable alignment states. Such angular alignment flexibility enables the system to compensate for variations in component tolerance, lens pitch, and pixel arrangement without modifying the physical layout of the lens assembly or display panel.

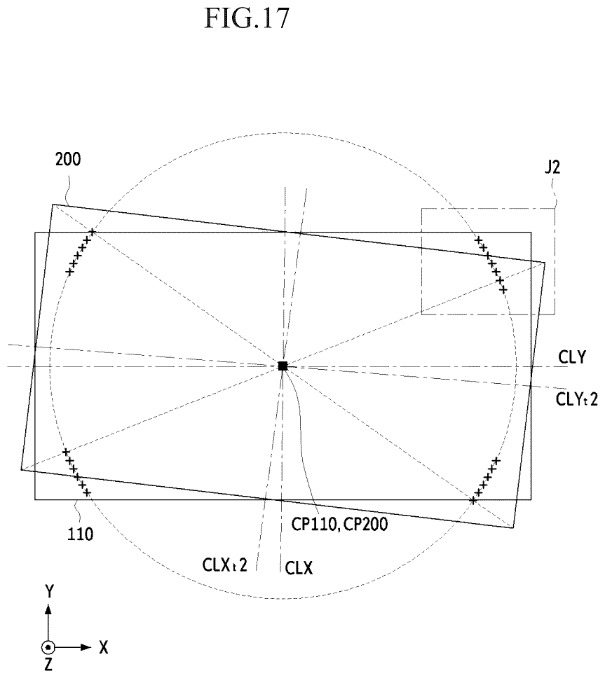

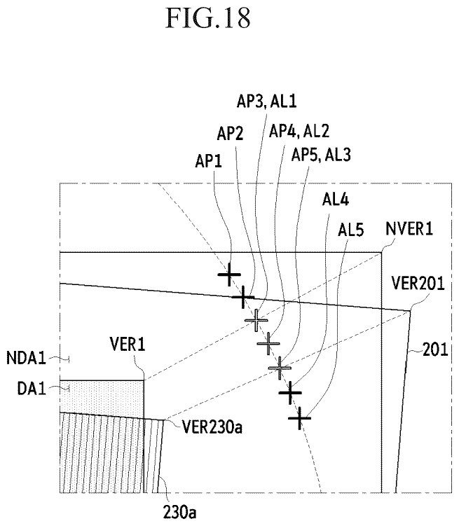

FIG. 17 is a plan view of a display device according to a second embodiment of the present disclosure. FIG. 18 is an enlarged view of portion J2 of FIG. 17.

Referring to FIGS. 17 and 18, in an embodiment, a third panel alignment mark AP3 may overlap a first optical alignment mark AL1 in the thickness direction, a fourth panel alignment mark AP4 may overlap a second optical alignment mark AL2 in the thickness direction, and a fifth panel alignment mark AP5 may overlap a third optical alignment mark AL3 in the thickness direction. This configuration illustrates a different rotational offset between the lens assembly 200 and the display panel 110 compared to FIG. 15, where the alignment overlap sequence is shifted.

The first optical alignment mark AL1 may be located on a straight line connecting a first panel inner vertex VER1 and a first panel outer vertex NVER1. The fifth panel alignment mark AP5 may be located on a straight line connecting a first lens assembly inner vertex VER230a and a first lens assembly outer vertex VER201.

In a display device, according to an embodiment, the smaller the first angle is formed, the easier to respond to a tilt angle in display devices having various sizes. A distance between alignment marks corresponds to the first angle. As the first angle becomes smaller, the angular resolution of the alignment system improves, allowing finer control during the attachment of the lens assembly 200. However, the smaller the first angle is formed, the easier to reduce the moire phenomenon and prevent deterioration of display quality in various display devices having various sizes.

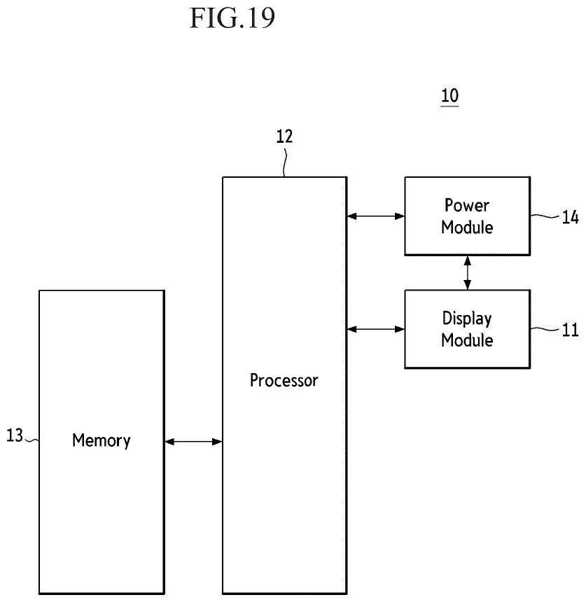

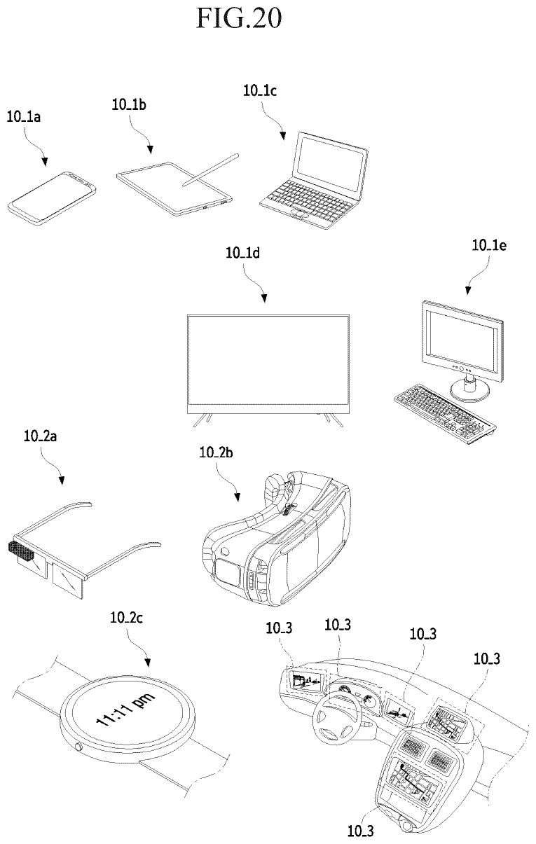

FIG. 19 is a block diagram of an electronic device according to an embodiment of the present disclosure. FIG. 20 is a schematic diagram of electronic devices according to various embodiments of the present disclosure.

Referring to FIG. 19, an electronic device 10 according to an embodiment may include a display module 11, a processor 12, a memory 13, and a power module 14. The display module 11 may be an example of, or includes aspects of, the display module 100 described with reference to FIG. 1.

The processor 12 may include at least one of a central processing unit (CPU), an application processor (AP), a graphic processing unit (GPU), a communication processor (CP), an image signal processor (ISP), and a controller.

The memory 13 may store data for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate power necessary for the operation of the electronic device 10 by converting power supplied by the power supply module.

At least one of the elements of the electronic device 10 described above may be included in a display device according to the above-described embodiments. In some cases, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 10.

In one embodiment, the processor 12, memory 13, and power module 14 may be electrically connected to the display module 11 via internal buses or other interfaces. These interconnections may be implemented using a flexible printed circuit (FPC), board-to-board connectors, or integrated substrates within the electronic device 10.

Referring to FIG. 20, various electronic devices to which display devices, according to embodiments of the present disclosure, are applied may include image display electronic devices such as a smartphone 10_1a, a tablet 10_1b, a laptop computer 10_1c, a television 10_1d, and a computer monitor 10_1e. In some cases, the various electronic devices to which the display devices, according to the embodiments of the present disclosure, are applied may include wearable electronic devices including display modules, such as smart glasses 10_2a, a head-mounted display 10_2b, and a smart watch 10_2c, and vehicle electronic devices 10_3 including display modules, such as a center information display (CID) and a room mirror display placed on an instrument cluster, center fascia and dashboard of a vehicle.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not necessarily intended to be limiting.

What is claimed is:

1. A display device comprising:
a display panel comprising a display panel center, and a first panel alignment mark and a second panel alignment mark each spaced apart from the display panel center by a radial distance and spaced apart from each other by an arc length with respect to the display panel center; and
a lens assembly comprising a lens assembly center and a first optical alignment mark spaced apart from the lens assembly center by the radial distance.

2. The display device of claim 1, wherein:
a distance between the first panel alignment mark and the display panel center is equal to a distance between the first optical alignment mark and the lens assembly center.

3. The display device of claim 1, wherein:
the display panel center is located at an intersection point of a first central axis crossing a second central axis of the display panel.

4. The display device of claim 3, wherein:
the lens assembly center is located at an intersection point of a third central axis crossing a fourth central axis of the lens assembly.

5. The display device of claim 1, wherein the lens assembly further comprises:
a first substrate, a second substrate, and a lens disposed between the first substrate and the second substrate.

6. The display device of claim 1, wherein the lens assembly further comprises:
a second optical alignment mark spaced apart from the lens assembly center by the radial distance.

7. The display device of claim 6, wherein:
a first straight line connecting the display panel center and the first panel alignment mark and a second straight line connecting the display panel center and the second panel alignment mark form a first angle, and
a third straight line connecting the lens assembly center and the first optical alignment mark and a fourth straight line connecting the lens assembly center and the second optical alignment mark form the first angle.

8. The display device of claim 7, wherein:
the display panel center and the lens assembly center overlap in a thickness direction of the display panel, wherein the thickness direction is perpendicular to an upper surface of the display panel.

9. The display device of claim 8, wherein:
the second panel alignment mark overlaps the first optical alignment mark in the thickness direction.

10. The display device of claim 9, wherein:
the second straight line coincides with a line obtained by rotating the first straight line clockwise by the first angle, and
the fourth straight line coincides with a line obtained by rotating the third straight line clockwise by the first angle.

11. The display device of claim 4, wherein the lens assembly further comprises:
a second optical alignment mark spaced apart from the lens assembly center,
a first straight line connecting the display panel center and the first panel alignment mark,
a second straight line connecting the display panel center and the second panel alignment mark,
a third straight line connecting the lens assembly center and the first optical alignment mark, and
a fourth straight line connecting the lens assembly center and the second optical alignment mark,
wherein the first straight line and the second straight line form a first angle,
wherein the third straight line and the fourth straight line form the first angle, and
the first central axis and the third central axis form the first angle.

12. The display device of claim 11, wherein:
the second central axis and the fourth central axis form the first angle.

13. The display device of claim 11, wherein:
the first angle is an acute angle.

14. A display device comprising:
a display panel comprising a display panel center, a first display panel portion, and a second display panel portion disposed adjacent to the first display panel portion; and
a lens assembly comprising a lens assembly center, a first lens assembly portion, and a second lens assembly portion disposed adjacent to the first lens assembly portion,
wherein each of the first display panel portion and the second display panel portion comprises a first panel alignment mark and a second panel alignment mark each spaced apart from the display panel center by a radial distance and spaced apart from each other by an arc length with respect to the display panel center, each of the first lens assembly portion and the second lens assembly portion comprises a first optical alignment mark spaced apart from the lens assembly center by the radial distance.

15. The display device of claim 14, wherein:
the second panel alignment mark of the first display panel portion overlaps the first optical alignment mark of the first lens assembly portion in a thickness direction of the display panel,
the second panel alignment mark of the second display panel portion overlaps the first optical alignment mark of the second lens assembly portion in the thickness direction, and
the thickness direction is perpendicular to an upper surface of the display panel.

16. The display device of claim 14, wherein:
a portion of the first display panel portion and a portion of the second display panel portion meet form a first central axis, and
a portion of the first lens assembly portion and a portion of the second lens assembly portion meet form a second central axis.

17. The display device of claim 14, wherein:
a distance between the first panel alignment mark of the first display panel portion and the display panel center is equal to a distance between the first panel alignment mark of the second display panel portion and the display panel center.

18. An electronic device comprising:
a processor providing an image signal;
a display module receiving the image signal from the processor and displaying an image; and
a power module supplying power to the display module,
wherein the display module comprises:
a display panel comprising a display panel center, and a first panel alignment mark and a second panel alignment mark each spaced apart from the display panel center by a radial distance and spaced apart from each other by an arc length with respect to the display panel center; and
a lens assembly comprising a lens assembly center and a first optical alignment mark spaced apart from the lens assembly center by the radial distance.

19. The electronic device of claim 18, wherein:
a distance between the first panel alignment mark and the display panel center is equal to a distance between the first optical alignment mark and the lens assembly center.

20. The electronic device of claim 18, wherein the lens assembly further comprises:
a second optical alignment mark spaced apart from the lens assembly center by the radial distance.
